(19) United States
(12) Patent Application Publication
(10) Pub. No.: US 2025/0305888 A1
(43) Pub. Date: Oct. 2, 2025

(54) RESISTIVE SENSORS AND METHODS OF FORMATION

(71) Applicant: Taiwan Semiconductor Manufacturing Company, Ltd., Hsinchu (TW)

(72) Inventors: Hsiang-Sheng HUANG, Zhubei City (TW); Wei-Jen CHANG, Miaoli County (TW); Pin-Chieh CHIU, New Taipei City (TW); Chung-Shih CHIANG, Zhubei City (TW)

(21) Appl. No.: 18/622,121

(22) Filed: Mar. 29, 2024

(51) Int. Cl. G01K 7/22; G01R 19/00

(52) U.S. Cl. CPC G01K 7/22; G01R 19/0092

(57) ABSTRACT

Some resistive sensor structures described herein include a main thin-film resistor segment and one or more selectable thin-film resistor segments that are connected in series (e.g., together and with the main thin-film resistor). The selectable thin-film resistor segment(s) of a resistive sensor structure described herein are capable of being selectively activated and/or deactivated based on the desired resistance and/or temperature coefficient of resistance (TCR) for the resistive sensor structure. Various structural implementations of control gates that may be used to selectively activate and/or deactivate one or more of the selectable thin-film resistor are disclosed herein.

### BACKGROUND

Semiconductor-based integrated circuits may include a wide range of semiconductor devices. These semiconductor devices may include active semiconductor devices and/or passive semiconductor devices. Active semiconductor devices may include transistors and other semiconductor devices that operate using a power source. Passive semiconductor devices include inductors, capacitors, resistors, and/or other semiconductor devices that can operate without a power source.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams of example implementations of a tunable resistive sensor structure described herein.

FIGS. 3A and 3B are diagrams of example operational configurations for a resistive sensor structure described herein.

FIGS. 4A-4D are diagrams of an example of forming a resistive sensor structure described herein.

FIGS. 5A-5I are diagrams of example implementations of a tunable resistive sensor structure described herein.

FIGS. 6A-6C are diagrams of example implementations of a tunable resistive sensor structure described herein.

FIGS. 7A and 7B are diagrams of example operational configurations for a resistive sensor structure described herein.

FIGS. 8A and 8B are diagrams of example implementations of a tunable resistive sensor structure described herein.

FIGS. 9A-9C are diagrams of example implementations of a tunable resistive sensor structure described herein.

FIGS. 10A and 10B are diagrams of example operational configurations for a resistive sensor structure described herein.

FIGS. 11A and 11B are diagrams of example implementations of a tunable resistive sensor structure described herein.

FIGS. 12A-12C are diagrams of example implementations of a tunable resistive sensor structure described herein.

FIGS. 13A and 13B are diagrams of example operational configurations for the resistive sensor structure described herein.

FIGS. 14A-14H are diagrams of an example of forming a resistive sensor structure described herein.

FIGS. 15A and 15B are diagrams of example implementations of a tunable resistive sensor structure described herein.

FIGS. 16A-16C are diagrams of example implementations of a tunable resistive sensor structure described herein.

FIGS. 17A-17I are diagrams of an example of forming a resistive sensor structure described herein.

FIGS. 18A and 18B are diagrams of example implementations of a tunable resistive sensor structure described herein.

FIG. 19 is a diagram of example components of a device described herein.

FIG. 20 is a flowchart of an example process associated with forming a resistive sensor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A resistor structure (e.g., a thin-film resistor (TFR) and/or another type of resistor structure) may be used in many applications such as resistor-capacitor (RC) circuits, power drivers, power amplifiers, thermal sensors, current meters, and/or radio frequency (RF) applications, among other examples. Some applications for a resistor structure are sensitive to one or more parameters of the resistor structure. For example, when used in a measurement circuit such as a thermal sensor circuit or a current meter circuit, the temperature coefficient of resistance (TCR) may directly affect the measurement accuracy of the measurement circuit. The TCR of a resistor structure is a numerical representation of the sensitivity of the resistance of the resistor structure to changes in temperature. The TCR of a resistor structure is typically expressed in parts per million per degree Celsius (ppm/° C.) or parts per million per degree Kelvin (ppm/° K). A resistor structure with a high TCR (e.g., a high sensitivity in resistance to changes in temperature) may enable more precise temperature measurements for a thermal sensor circuit than a resistor structure with a low TCR. However, a resistor structure with a high TCR may result in ambient temperature having a greater influence on current measurements in a current meter circuit because the resistor structure is more susceptible to changes in resistance, resulting in less accurate current measurements than if a resistor structure with a low TCR (that is less susceptible to changes in resistance due to temperature) were used in the current meter circuit.

In some cases, a resistor structure may be manufactured to have a particular TCR (or to have a TCR within a particular range). However, the TCR of the resistor structure is unable to be modified after manufacturing. This may limit the use of the resistor structure to a specific purpose. Manufacturing resistor structures on a semiconductor device to have different TCRs for different applications or purposes results in increased semiconductor design and manufacturing cost and complexity. Moreover, the TCR may vary across multiple resistor structures due to process variation in semiconductor manufacturing after manufacturing, resulting in errors in measurements based on the resistance and/or TCR of the resistor structures.

Various implementations described herein include resistive sensor structures that have a tunable resistance after manufacturing. One or more of the resistive sensor structures described herein may be implemented as a measurement circuit such as a current meter circuit, a thermal sensor circuit, and/or another type of measurement circuit. The resistance of a resistive sensor structure described herein can be tuned or trimmed to compensate for semiconductor manufacturing variation and/or to enable flexible use of the resistive sensor structure by enabling the TCR of the resistive sensor structure to be tuned or trimmed without having to manufacture the resistive sensor structure to have a single particular TCR.

Some resistive sensor structures described herein include a main thin-film resistor segment and one or more selectable thin-film resistor segments that are connected in series (e.g., together and with the main thin-film resistor). The selectable thin-film resistor segments of resistive sensor structures described herein are capable of being selectively activated and/or deactivated based on the desired resistance and/or TCR for each resistive sensor structure. Various structural implementations of control gates that may be used to selectively activate and/or deactivate one or more of the selectable thin-film resistors are disclosed herein. Examples of such control gates include transmission gates, programmable control gates (e.g., switches, memory structures, other logic structures), and/or trim pads, and/or a combination thereof, among other examples.

In this way, the resistive sensor structures in a semiconductor device described herein may be configured for particular types of measurement circuits without having to manufacture the resistive sensor structures to have a single particular TCR. This reduces the manufacturing complexity of the resistive sensor structures and/or enables the resistive sensor structures to be used for more than one type of measurement circuit. In particular, the TCR of a resistive sensor structure described herein may be modified during operation of the semiconductor device, enabling the resistive sensor structure to be repurposed for different types of measurements instead of (or in addition to) including different measurement circuits for the different types of measurements. Additionally and/or alternatively, the resistance and/or TCR of the resistive sensor structure may be modified after manufacturing of the resistive sensor structure to correct or compensate for semiconductor process variation during manufacturing of the resistive sensor structure.

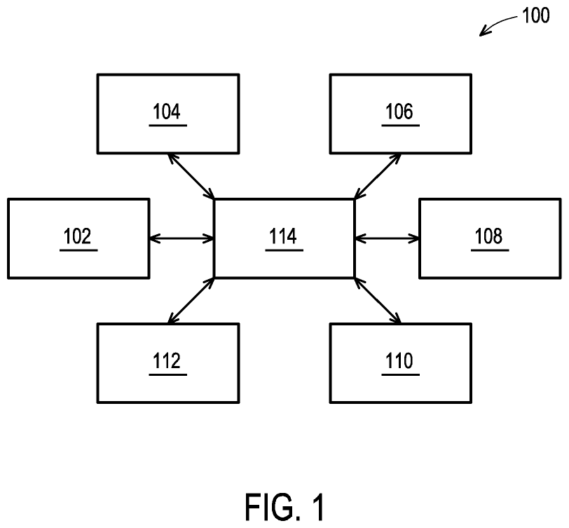

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

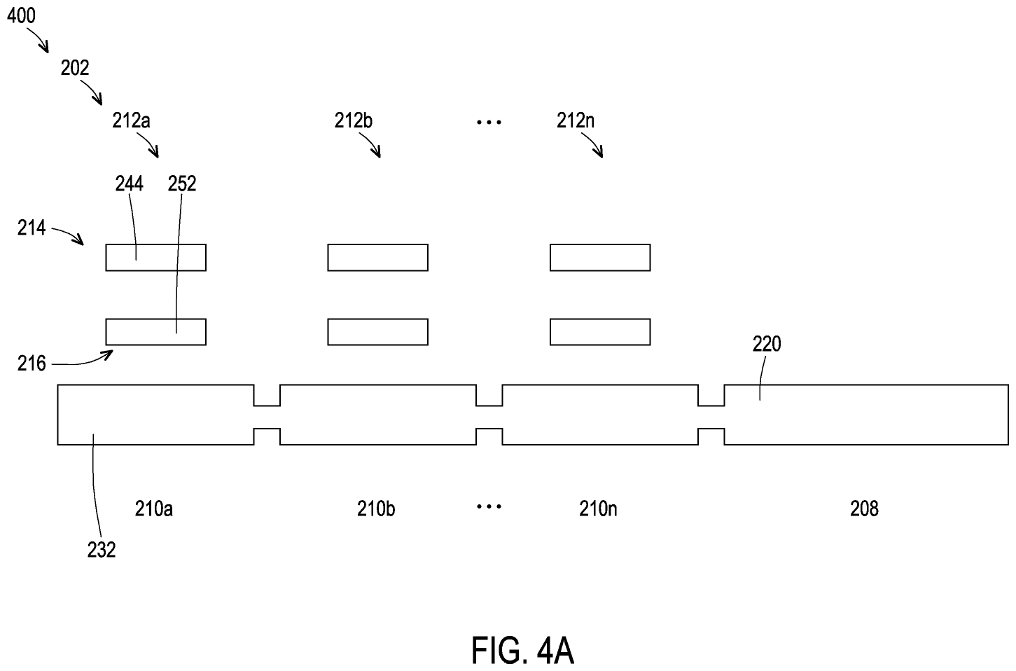

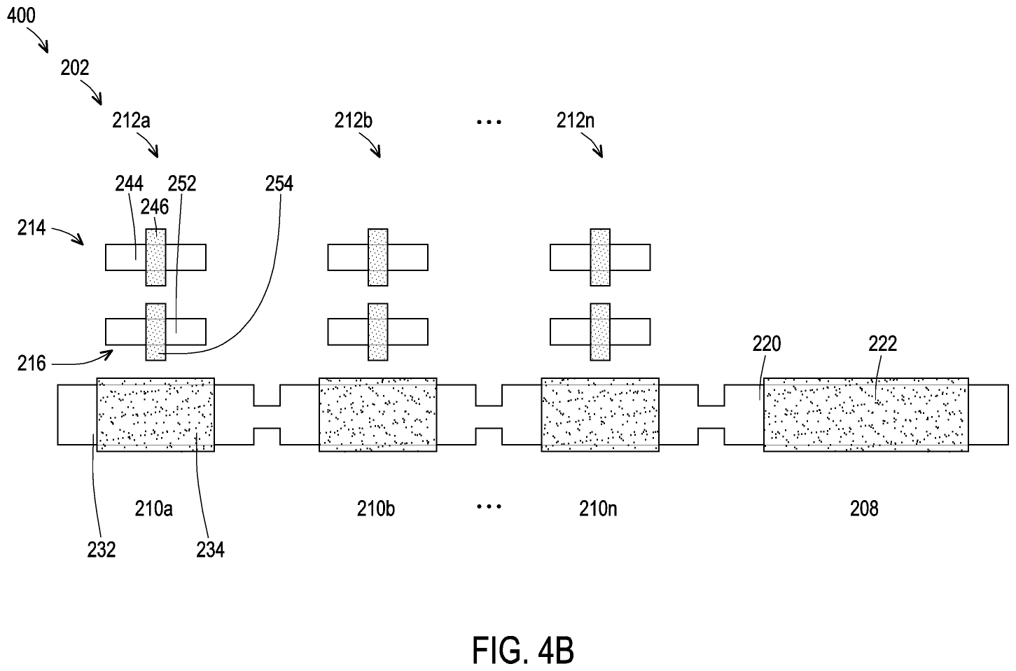

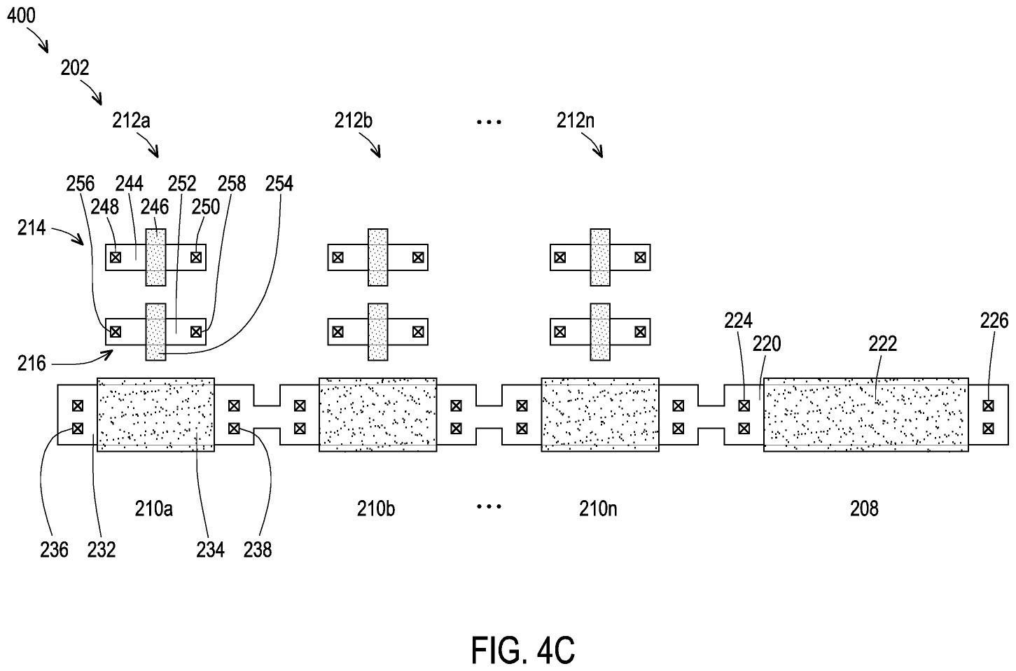

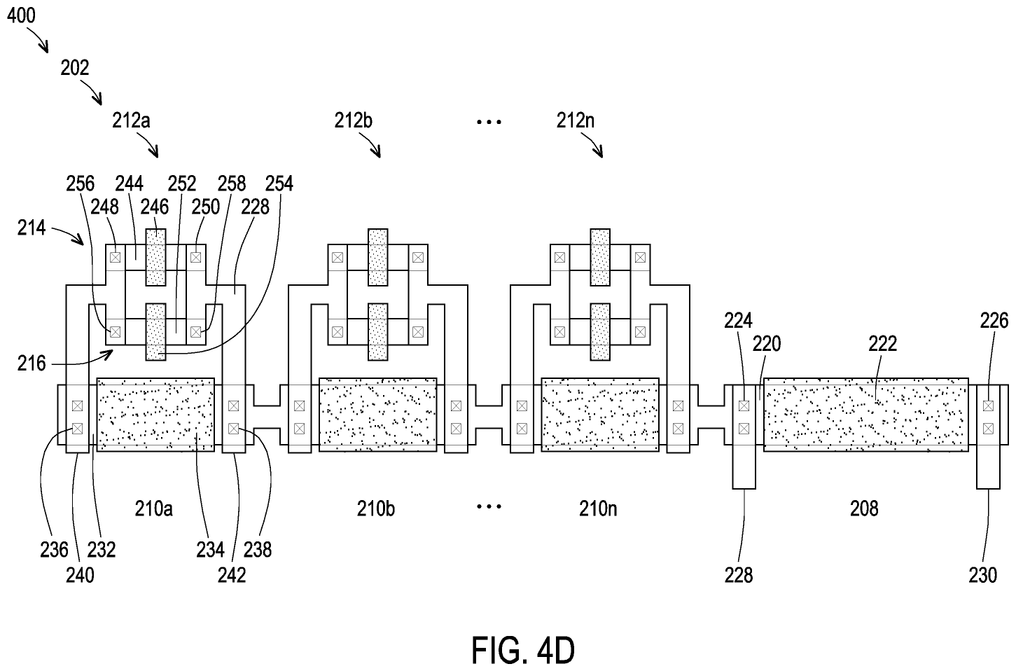

In some implementations, one or more of the semiconductor processing tools 102-112 and/or the wafer/die transport tool 114 may be used to perform one or more semiconductor processing operations described herein. For example, one or more of the semiconductor processing tools 102-112 and/or the wafer/die transport tool 114 may be used to form a thin-film resistor of a resistive sensor structure, and/or form a resistance trimming structure of the resistive sensor structure, where the resistance trimming structure is electrically coupled with the thin-film resistor in series, among other examples. In some implementations, one or more of the semiconductor processing tools 102-112 and/or the wafer/die transport tool 114 may be used to perform one or more semiconductor processing operations described in connection with FIGS. 4A-4D, 14A-14H, 17A-17I, and/or 20, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

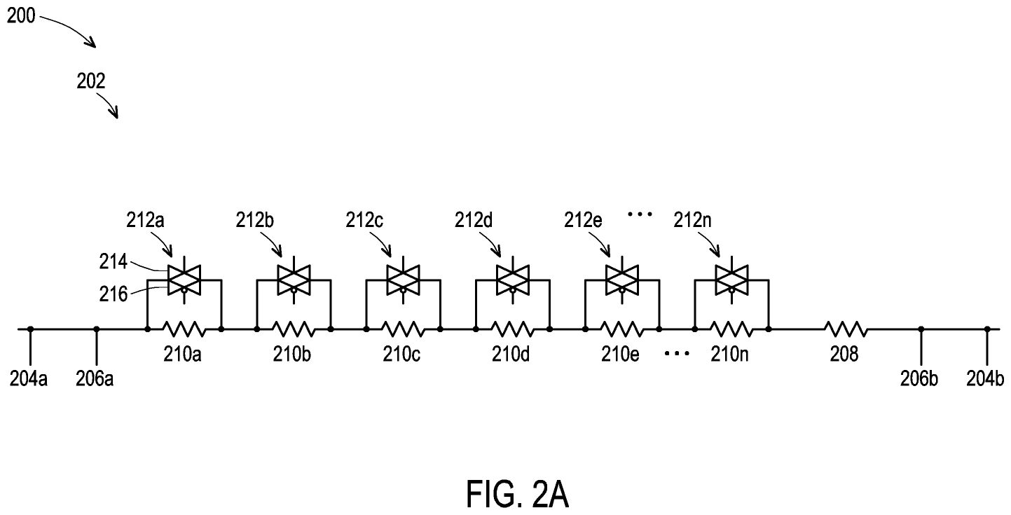

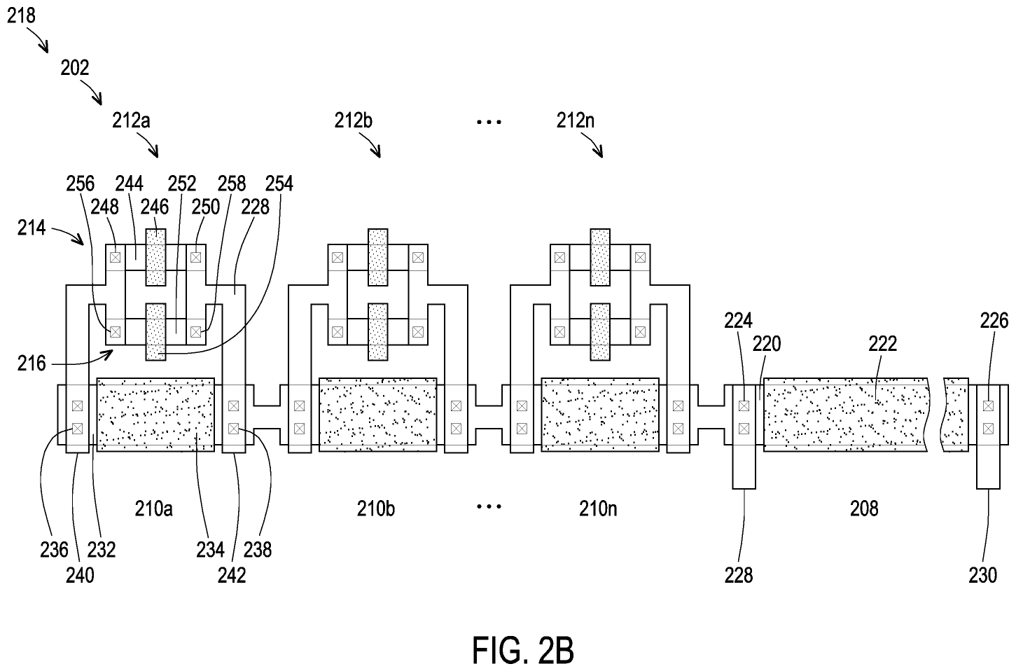

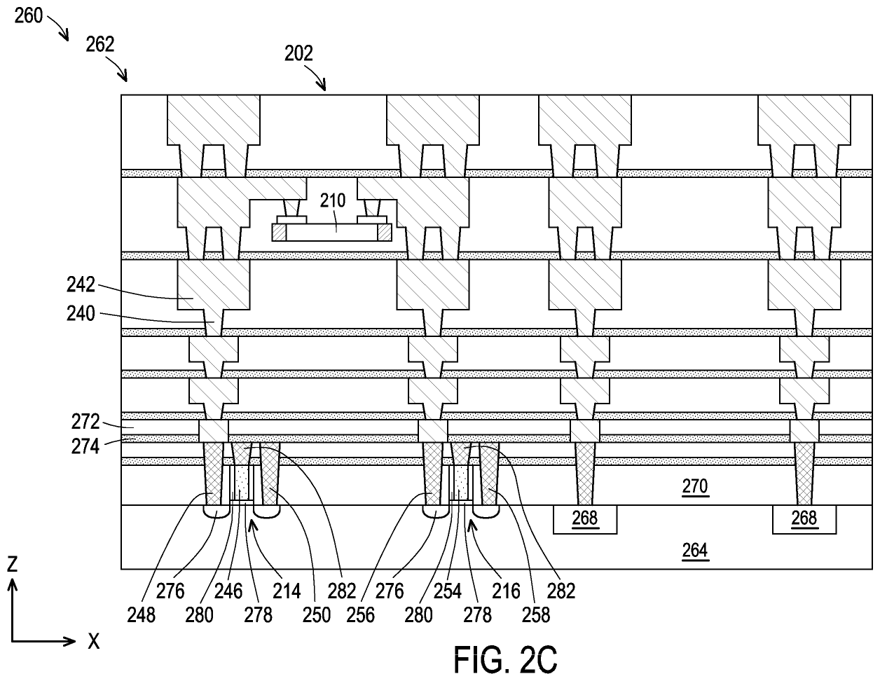

FIGS. 2A-2C are diagrams of example implementations of a tunable resistive sensor structure described herein. FIG. 2A illustrates an example 200 of a circuit implementation for a resistive sensor structure 202. The resistive sensor structure 202 includes one or more inputs 204a, 204b, and one or more sensing terminals 206a, 206b. The resistive sensor structure 202 may be configured as a current meter (e.g., a sensor that is configured to sense a magnitude of a current on the inputs 204a, 204b based on a resistance of the resistive sensor structure 202), a thermal sensor (e.g., a sensor that is configured to sense a temperature based on a current on the inputs 204a, 204b), and/or another type of resistance-based sensor.

The resistive sensor structure 202 is a tunable resistive sensor structure in that the resistive sensor structure 202 includes a main thin-film resistor 208 electrically coupled with a plurality of selectable thin-film resistors 210a-210n. The selectable thin-film resistors 210a-210n are capable of being selectively enabled or disable to achieve a particular overall resistance (or a particular overall TCR) for the resistive sensor structure 202, and/or modify the resistance (or the TCR) for the resistive sensor structure 202. The selectable thin-film resistors 210a-210n are electrically coupled in series, and the selectable thin-film resistors 210a-210n are electrically coupled with the main thin-film resistor 208 in series. Thus, the overall resistance of the resistive sensor structure 202 corresponds to the resistance of the main thin-film resistor 208, plus the resistance of any activated selectable thin-film resistors of the selectable thin-film resistors 210a-210n. For example, if selectable thin-film resistors 210a and 210b are activated, the overall resistance of the resistive sensor structure 202 corresponds to the combination of the resistance of the main thin-film resistor 208 and the resistances of the selectable thin-film resistors 210a and 210b, and similarly for the overall TCR of the resistive sensor structure 202.

The selectable thin-film resistors 210a-210n may be selectable using control gates 212a-212n that are included in the resistive sensor structure 202. Thus, the selectable thin-film resistors 210a-210n and the control gates 212a-212n may correspond to a resistance trimming structure of the resistive sensor structure 202. Each of the selectable thin-film resistors 210a-210n may be electrically coupled in parallel with a control gate of the control gates 212a-212n. For example, the selectable thin-film resistor 210a may be electrically coupled with the control gate 212a in parallel, the selectable thin-film resistor 210b may be electrically coupled with the control gate 212b in parallel, and so on. Moreover, the control gates 212a-212n are electrically connected in series with each other.

The control gates 212a-212n are configured to selectively control the flow of electrical current between the inputs 204a, 204b and the sensing terminals 206a, 206b. For example, control gate 212a is configured to selectively control the flow of electrical current between the inputs 204a, 204b and the sensing terminals 206a, 206b to be either through the selectable thin-film resistor 210a (in which case the selectable thin-film resistor 210a is considered to be selected or activated) or through the control gate 212a (in which case the selectable thin-film resistor 210a is considered to be deselected or deactivated).

When the selectable thin-film resistor 210a is activated, the control gate 212a is in an off state such that the control gate 212a functions as an open circuit. Thus, the path of least electrical resistance is through the selectable thin-film resistor 210a, and the resistance (and TCR) of the selectable thin-film resistor 210a contributes to the overall resistance (and overall TCR) of the resistive sensor structure 202.

When the selectable thin-film resistor 210a is deactivated, the control gate 212a is in an on state such that the control gate 212a functions as a short circuit. Thus, the path of least electrical resistance is through the control gate 212a, and electrical current flows around the selectable thin-film resistor 210a through the control gate 212a. When the selectable thin-film resistor 210a is deactivated, the selectable thin-film resistor 210a does not contribute to the overall resistance (or overall TCR) of the resistive sensor structure 202.

The selectable thin-film resistors 210b-210n and the control gates 212b-212n operate in a similar manner as described above in connection with the selectable thin-film resistor 210a and the control gate 212a.

Each of the control gates 212b-212n includes a transmission gate, which is a complementary metal oxide semiconductor based (CMOS-based) switch that includes an n-type metal oxide semiconductor (NMOS) transistor (e.g., an NMOS field effect transistor or (NFET) 214 electrically coupled in parallel with a p-type metal oxide semiconductor (PMOS) transistor (e.g., a PMOS field effect transistor or PFET) 216). An input (e.g., a voltage input) may be provided to the gate of the NMOS transistor 214 of the transmission gate, and an inverted input (e.g., an inverted voltage input) may be provided to the gate of the PMOS transistor 216, to switch the transmission gate to an on (e.g., conducting) state. The absence of an input on the transmission gate results in the transmission gate being an in off (e.g., non-conducting) state.

FIG. 2B illustrates an example 218 of a structural implementation of the resistive sensor structure 202. As shown in FIG. 2B, the main thin-film resistor 208 includes an active region 220 (e.g., an electrically resistive layer), a resist protective oxide (RPO) layer 222 over the active region 220, a plurality of contacts 224 and 226 on opposing sides of the active region 220, and metallization layers 228 and 230 respectively coupled with the contacts 224 and 226. Each of the selectable thin-film resistors 210b-210n similarly includes an active region 232 (e.g., an electrically resistive layer), an RPO layer 234 over the active region 232, a plurality of contacts 236 and 238 on opposing sides of the active region 232, and metallization layers 240 and 242 respectively coupled with the contacts 236 and 238. In some implementations, the inputs 204a, 204b and/or the sensing terminals 206a, 206b may be electrically connected to the metallization layers 228 and/or 230.

The selectable thin-film resistors 210a-210n are electrically coupled in series through the active regions 232 of the selectable thin-film resistors 210a-210n. For example, the selectable thin-film resistors 210a and 210b are electrically connected in series through the active regions 232 of the selectable thin-film resistors 210a and 210b, the selectable thin-film resistors 210b and 210c are electrically connected in series through the active regions 232 of the selectable thin-film resistors 210b and 210c, and so on. The main thin-film resistor 208 is electrically coupled in series with the selectable thin-film resistors 210a-210n through the active regions 232 of the selectable thin-film resistors 210a-210n and the active region 220 of the main thin-film resistor 208.

The metallization layers 240 and 242 may electrically connect the selectable thin-film resistors 210a-210n with associated control gates 212a-212n. For example, metallization layers 240 and 242 may electrically connect the selectable thin-film resistor 210a with the control gate 212a, metallization layers 240 and 242 may electrically connect the selectable thin-film resistor 210b with the control gate 212b, and so on. Each of the control gates 212a-212n includes an NMOS transistor 214 and a PMOS transistor 216 electrically connected in series.

The NMOS transistor 214 may include an active region 244, a gate structure 246, and a plurality of contacts 248 and 250 connected to the active region 244 on opposing sides of the gate structure 246. The active region 244, the gate structure 246, and/or another region of the NMOS transistor 214 may be doped with one or more n-type dopants, such as phosphorous (P) and/or arsenic (As), among other examples.

The PMOS transistor 216 may include an active region 252, a gate structure 254, and a plurality of contacts 256 and 258 connected to the active region 252 on opposing sides of the gate structure 254. The active region 252, the gate structure 254, and/or another region of the PMOS transistor 216 may be doped with one or more p-type dopants, such as boron (B) and/or gallium (Ga), among other examples.

The contacts 248 and 256 may respectively connect the NMOS transistor 214 and the PMOS transistor 216 with the metallization layer 240. The contacts 250 and 258 may respectively connect the NMOS transistor 214 and the PMOS transistor 216 with the metallization layer 242.

The active region 220 of the main thin-film resistor 208 and the active regions 232 of the selectable thin-film resistors 210a-210n may each include a layer of electrically resistive material. Examples of such materials include nickel chromium (nichrome or NiCr), tantalum nitride (TaN), polysilicon, and/or another suitable electrically resistive thin-film material. The active regions 244 and 252, respectively of the NMOS transistor 214 and the PMOS transistor 216, may each include silicon (Si), silicon germanium (SiGe), and/or another suitable channel material.

The RPO layer 222 of the main thin-film resistor 208 and the RPO layers 234 of the selectable thin-film resistors 210a-210n may each include a layer of dielectric material such as a silicon oxide (SiOₓ), a silicon nitride (SiₓN_{y}), and/or a silicon oxynitride (SiON), among other examples. The RPO layer 222 and the RPO layers 234 may be included to block or reduce the likelihood of silicidation of the active region 220 and the active regions 232, respectively. Silicidation might otherwise occur during formation of metal silicide layers during the process of forming the contacts, 236, 238, 240, and/or 242. The RPO layer 222 and the RPO layers 234 may alternatively be referred to as silicide blocking layers or silicide alignment blocks.

The gate structures 246 and 254, respectively, of the NMOS transistor 214 and the PMOS transistor 216, may each include polysilicon, one or more metals (e.g., tungsten (W), cobalt (Co), titanium (Ti)), and/or one or more high dielectric constant (high-k) materials (e.g., hafnium oxide (HfOₓ)), among other examples. In some implementations, the gate structure 246 of the NMOS transistor 214 includes one or more n-type work function materials for tuning the work function of the NMOS transistor 214. In some implementations, the gate structure 254 of the PMOS transistor 216 includes one or more p-type work function materials for tuning the work function of the PMOS transistor 216.

FIG. 2C illustrates an example 260 of a structural implementation of a semiconductor device 262 in which the resistive sensor structure 202 may be included. The semiconductor device 262 may include a system on chip (SoC) device, a logic device such as a central processing unit (CPU) or a graphics processing unit (GPU), a memory device (e.g., a high bandwidth memory (HBM) device), a CMOS image sensor device, and/or another type of semiconductor device.

As shown in FIG. 2C, the semiconductor device 262 includes a substrate 264. The substrate 264 may correspond to a portion of a semiconductor wafer on which the semiconductor device 262 is formed. The substrate 264 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 264 may extend in an x-direction and/or in a y-direction in the semiconductor device 200.

The devices 268 may be included in and/or on the substrate 264. The devices 268 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices. In some implementations, the NMOS transistors 214 and/or the PMOS transistors 216 of the control gates 212a-212n are also included in and/or on the substrate 264. Additionally and/or alternatively, the NMOS transistors 214 and/or the PMOS transistors 216 of the control gates 212a-212n may be included in one or more dielectric layers above the substrate 264.

A dielectric layer 270 is included over the substrate 264. The dielectric layer 270 includes an interlayer dielectric (ILD) layer, an etch stop layer (ESL), and/or another type of dielectric layer. The dielectric layer 270 includes dielectric material(s) that enable various portions of the substrate 264 to be selectively etched or protected from etching, and/or may electrically isolate the devices 268 in and/or on the substrate 264. The dielectric layer 270 includes a silicon nitride (SiₓN_{y}), an oxide (e.g., a silicon oxide (SiOₓ) and/or another oxide material), and/or another type of dielectric material. The dielectric layer 270 may extend in the x-direction and/or in a y-direction in the semiconductor device 200.

The semiconductor device 262 further includes a plurality of dielectric layers that are arranged in a direction (e.g., the z-direction) that is approximately perpendicular to the substrate 264. The dielectric layers may include dielectric layers 272 and ESLs 274 that are arranged in an alternating manner in the z-direction. The dielectric layers 272 and the ESLs 274 may extend in the x-direction and/or in a y-direction in the semiconductor device 262.

The dielectric layers 272 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, a dielectric layer 272 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 274 may each include a silicon nitride (SiₓN_{y}), silicon carbide (SiC), silicon oxynitride (SiON), and/or another suitable dielectric material. In some implementations, a dielectric layer 272 and an ESL 274 include different dielectric materials to provide etch selectivity to enable various structures to be formed.

An NMOS transistor 214 of a control gate 212a-212n may include a gate structure 246 between source/drain regions 276. A PMOS transistor 216 of a control gate 212a-212n may similarly include a gate structure 254 between source/drain regions 276. “Source/drain region(s)” may refer to a source or a drain, individually or collectively, dependent upon the context. The active region 244 of the NMOS transistor 214 may include a portion of the substrate 264 that is between the source/drain regions 276 and under the gate structure 246. The active region 252 of the PMOS transistor 216 may include a portion of the substrate 264 that is between the source/drain regions 276 and under the gate structure 254.

A gate dielectric layer 278 may be included between the gate structure 246 and the substrate 264. A gate dielectric layer 278 may be similarly be included between the gate structure 254 and the substrate 264. In some implementations, a gate dielectric layer 278 includes a low dielectric constant (low-k) dielectric material such as silicon oxide (SiOₓ). In some implementations, a gate dielectric layer 278 includes a high-k dielectric material such as hafnium oxide (HfOₓ).

Sidewall spacers 280 may be included on the sidewalls of the gate structure 246 to provide electrical isolation for the gate structure 246, among other examples. Similarly, sidewall spacers 280 may be included on the sidewalls of the gate structure 254 to provide electrical isolation for the gate structure 254, among other examples. The sidewall spacers 280 may include a silicon oxide (SiOₓ), a silicon nitride (SiₓN_{y}), a silicon oxy carbide (SiOC), a silicon oxycarbonitride (SiOCN), and/or another suitable material.

The source/drain regions 276 of an NMOS transistor 214 may be electrically coupled and/or physically coupled with contacts 248 and 250 of the NMOS transistor 214. The source/drain regions 276 of a PMOS transistor 216 may be electrically coupled and/or physically coupled with contacts 256 and 258 of the PMOS transistor 216. The contacts 248, 250, 256, and 258 may each include contact vias, contact plugs, and/or another type of contact structures. The contacts 248, 250, 256, and 258 may include cobalt (Co), ruthenium (Ru), and/or another electrically conductive material or metal material. In some implementations, one or more liner layers may be included on sidewalls of the contacts 248, 250, 256, and/or 258. The liner layer(s) may include a barrier layer that is included to prevent or minimize diffusion of materials from the contacts 248, 250, 256, and/or 258 to the surrounding dielectric layers, an adhesion layer or glue layer that is included to promote adhesion between the contacts 248, 250, 256, and/or 258 and the surrounding dielectric layers, and/or another type of liner. Examples of materials for the liner layer(s) include titanium nitride (TiN), tantalum nitride (TaN), and/or another suitable liner material.

The gate structures 246 and 254 may each be electrically coupled and/or physically coupled with a gate contact 282. The gate contacts 282 may include contact vias, contact plugs, and/or another type of contact structures. The gate contacts 282 may each include cobalt (Co), ruthenium (Ru), and/or another electrically conductive material or metal material. One or more liner layers may be included on sidewalls of the gate contacts 282. The liner layer(s) may include a barrier layer that is included to prevent or minimize diffusion of materials from the gate contacts 282 to the surrounding dielectric layers, an adhesion layer or glue layer that is included to promote adhesion between the gate contacts 282 and the surrounding dielectric layers, and/or another type of liner. Examples of materials for the liner layer(s) include titanium nitride (TiN), tantalum nitride (TaN), and/or another suitable liner material.

As further shown in FIG. 2C, the metallization layers 240 and 242 may extend in the z-direction through the dielectric layers 272 and ESLs 274. The metallization layers 240 and 242 may each include a combination of trenches, vias, interconnects, and/or another type of conductive structure. The metallization layers 240 and 242 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the metallization layers 240, 242 and the surrounding dielectric layers. The one or more liner layers may include barrier liners, adhesion liners, and/or another type of liners. Examples of materials for the one or more liners include tantalum nitride (TaN) and/or titanium nitride (TiN), among other examples.

As indicated above, FIGS. 2A-2C are provided as examples. Other examples may differ from what is described with regard to FIGS. 2A-2C.

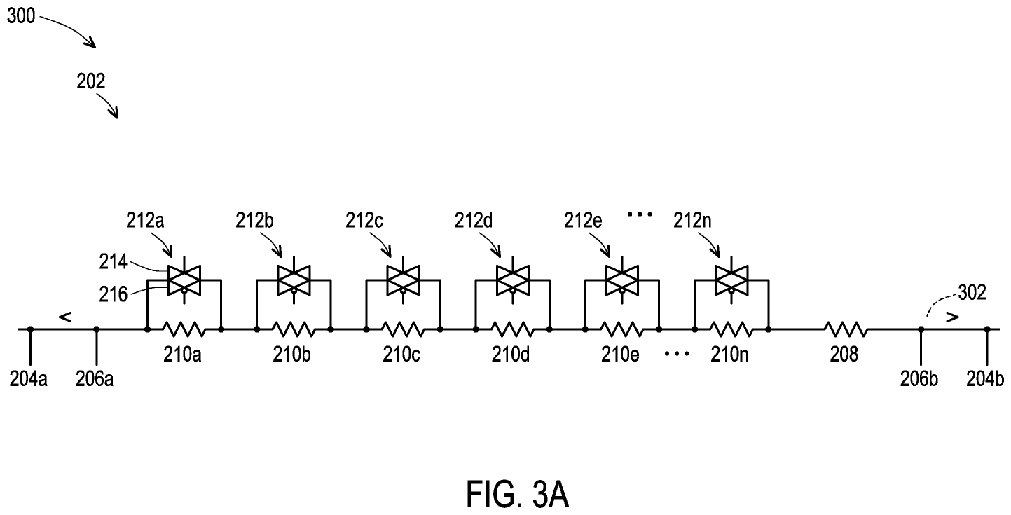

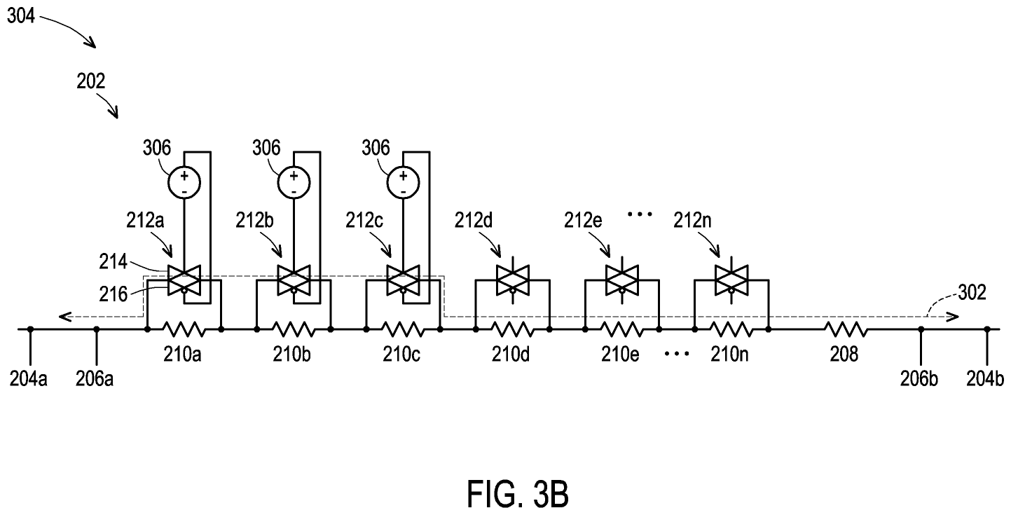

FIGS. 3A and 3B are diagrams of example operational configurations for the resistive sensor structure 202 described herein. FIG. 3A illustrates an example configuration 300 in which the control gates 212a-212n of the resistive sensor structure 202 are all in an off state. Thus, the selectable thin-film resistors 210a-210n of the resistive sensor structure 202 are activated, and a current flow path 302 through the resistive sensor structure 202 is through the selectable thin-film resistors 210a-210n in addition to the main thin-film resistor 208. Thus, the overall resistance (and the overall TCR) of the resistive sensor structure 202 corresponds to a combination of the respective resistances (and the respective TCRs) of the selectable thin-film resistors 210a-210n and the main thin-film resistor 208.

FIG. 3B illustrates an example configuration 304 in which the control gates 212a-212c of the resistive sensor structure 202 are all in an on state and the control gates 212d-212n of the resistive sensor structure 202 are in an off state. Thus, the selectable thin-film resistors 210a-210c of the resistive sensor structure 202 are deactivated and the selectable thin-film resistors 210d-210n of the resistive sensor structure 202 are activated. A voltage input 306 may be applied to the control gates 212a-212c to switch the control gates 212a-212c to the on state. The voltage input 306 may include a voltage that is applied to the NMOS transistor 214 and an inverted voltage that is applied to the PMOS transistor 216.

The current flow path 302 through the resistive sensor structure 202 in the example configuration 304 is through the selectable thin-film resistors 210d-210n in addition to the main thin-film resistor 208, and the selectable thin-film resistors 210a-210c are bypassed such that the current flow path 302 is through the control gates 212a-212c. Thus, only the overall resistance (and the overall TCR) of the resistive sensor structure 202 corresponds to a combination of the respective resistances (and the respective TCRs) of the selectable thin-film resistors 210d-210n and the main thin-film resistor 208.

In this way, the example operation configurations illustrated in FIGS. 3A and 3B illustrate the use of the selectable thin-film resistors 210d-210n to tune to the resistance and/or the TCR of the resistive sensor structure 202. The example operation configurations illustrated in FIGS. 3A and 3B are examples only, and other example operation configurations for tuning to the resistance and/or the TCR of the resistive sensor structure 202 are within the scope of the present disclosure.

As indicated above, FIGS. 3A and 3B are provided as examples. Other examples may differ from what is described with regard to FIGS. 3A and 3B.

FIGS. 4A-4D are diagrams of an example 400 of forming a resistive sensor structure 202 described herein. In some implementations, one or more of the semiconductor processing techniques and/or operations described in connection with FIGS. 4A-4D may be used and/or performed to form one or more of the other resistive sensor structures described herein. In some implementations, one or more of the semiconductor processing operations described in connection with FIGS. 4A-4D are performed using one or more of the semiconductor processing tools 102-112 and/or the wafer/die transport tool 114. In some implementations, one or more of the semiconductor processing operations described in connection with FIGS. 4A-4D are performed using another semiconductor processing tool.

As shown in FIG. 4A, the active region 220 of the main thin-film resistor 208, the active regions 232 of the selectable thin-film resistors 210a-210n, the active regions 244 of the NMOS transistors 214 of the control gates 212a-212n, and the active regions 252 of the PMOS transistors 216 of the control gates 212a-212n may be formed. In some implementations, the active regions 220, 232, 244, and/or 252 are formed in a substrate of a semiconductor device (e.g., the substrate 264 of the semiconductor device 262). In some implementations, a deposition tool 102 may be used to deposit the active regions 220, 232, 244, and/or 252 using a PVD technique, an ALD technique, a CVD technique, an epitaxy technique, an oxidation technique, another type of deposition technique described in connection with FIG. 1, and/or another suitable deposition technique.

As shown in FIG. 4B, the RPO layers 222 and 234 may be formed over the active regions 220 and 232, respectively. In some implementations, a deposition tool 102 may be used to deposit the RPO layers 222 and 234 using a PVD technique, an ALD technique, a CVD technique, an oxidation technique, another type of deposition technique described in connection with FIG. 1, and/or another suitable deposition technique. In some implementations, a planarization tool 112 may be used to planarize the RPO layers 222 and 234.

As further shown in FIG. 4B, the gate structures 246 of the NMOS transistors 214 and the gate structures 254 of the PMOS transistors 216 may be formed. A deposition tool 102 and/or a plating tool 112 may be used to deposit the gate structures 246 and/or 254 using a CVD technique, a PVD technique, an ALD technique, an electroplating technique, another deposition technique described above in connection with FIG. 1, and/or another suitable deposition technique.

As shown in FIG. 4C, contacts 224, 226, 236, 238, 248, 250, 256, and/or 258 may be formed. A deposition tool 102 and/or a plating tool 112 may be used to deposit the contacts 224, 226, 236, 238, 248, 250, 256, and/or 258 using a CVD technique, a PVD technique, an ALD technique, an electroplating technique, another deposition technique described above in connection with FIG. 1, and/or another suitable deposition technique.

As shown in FIG. 4D, metallization layers 228, 230, 240, and/or 242 may be formed. A deposition tool 102 and/or a plating tool 112 may be used to deposit the metallization layers 228, 230, 240, and/or 242 using a CVD technique, a PVD technique, an ALD technique, an electroplating technique, another deposition technique described above in connection with FIG. 1, and/or another suitable deposition technique.

As indicated above, FIGS. 4A-4D are provided as examples. Other examples may differ from what is described with regard to FIGS. 4A-4D.

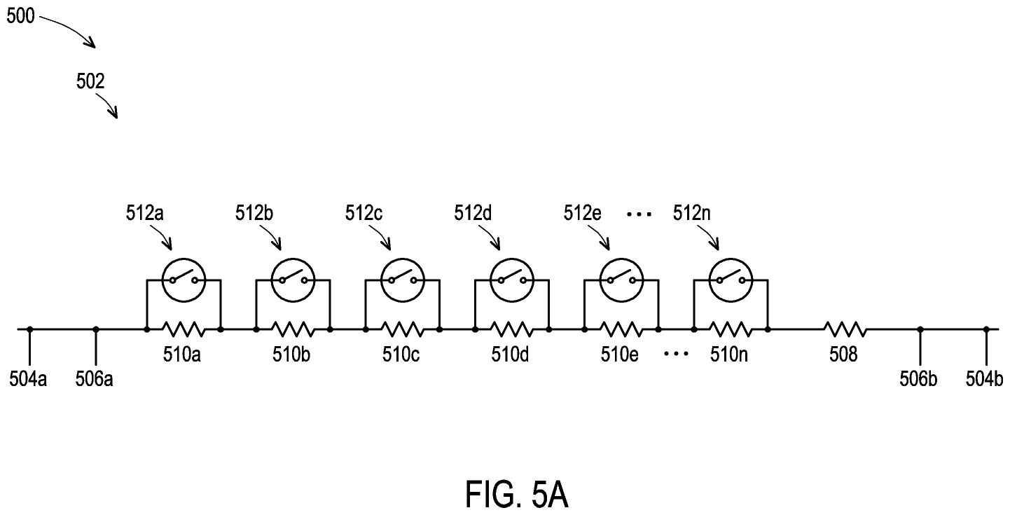

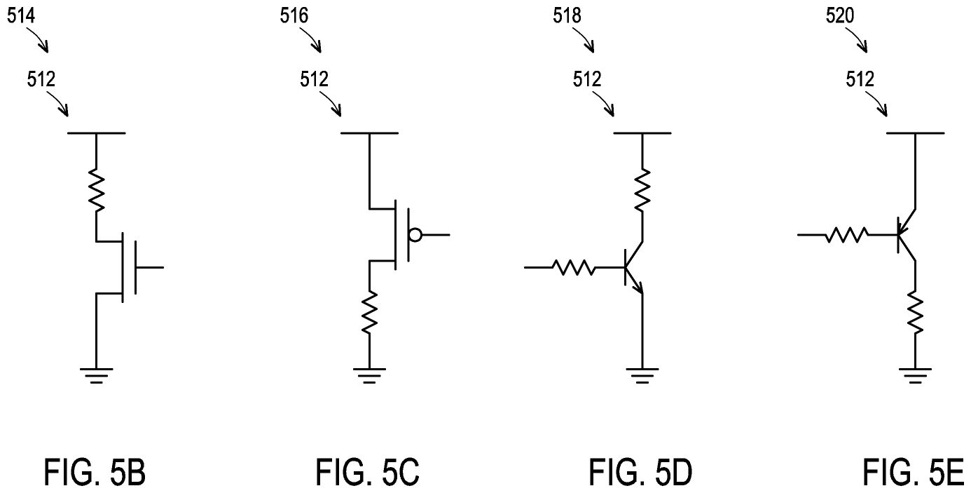

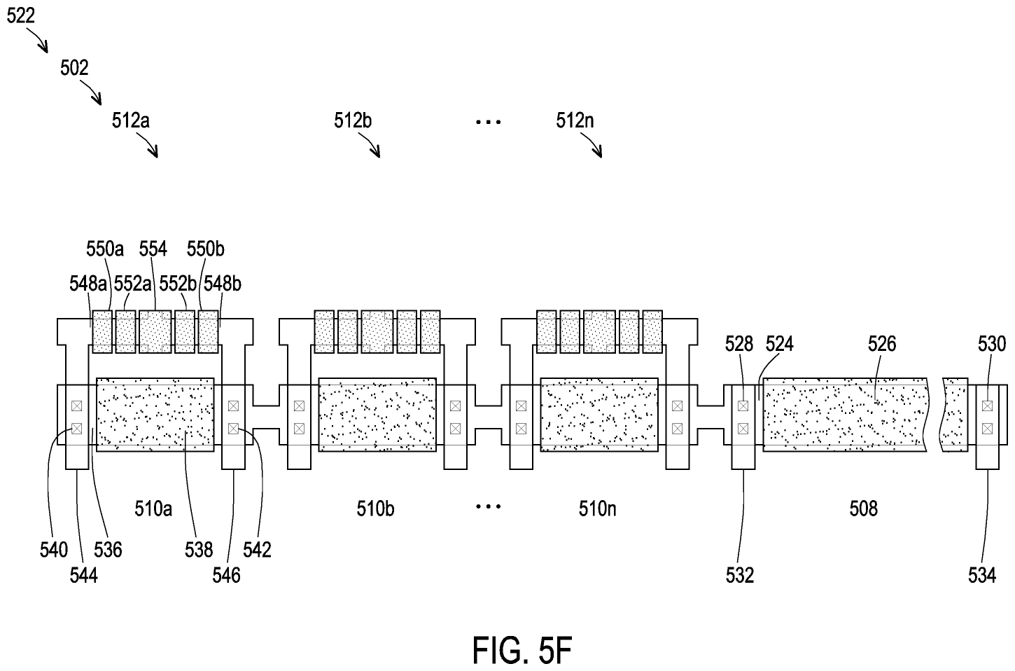

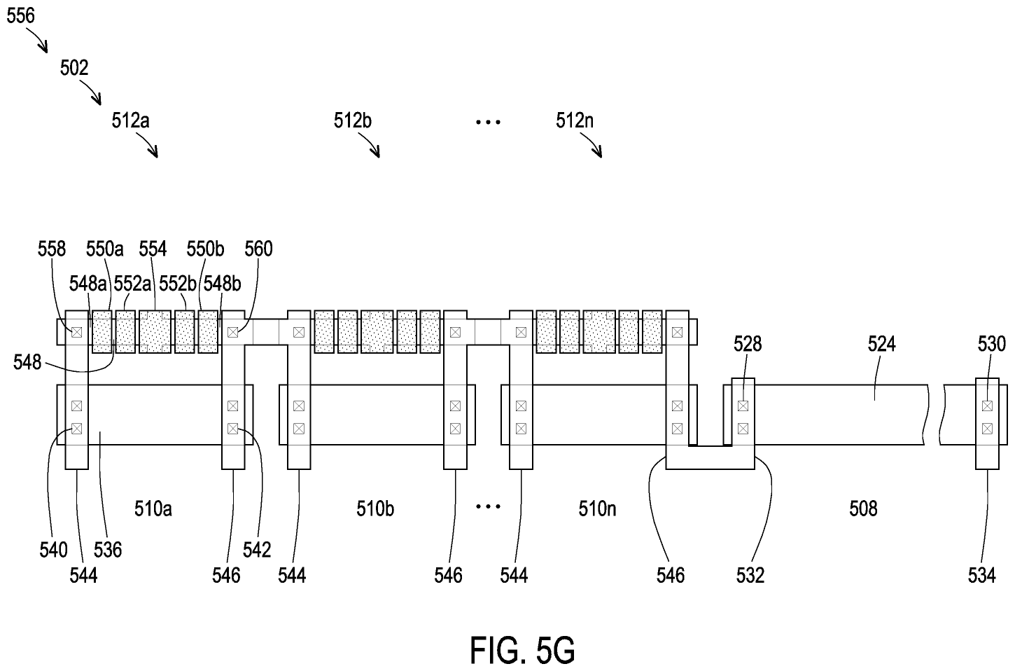

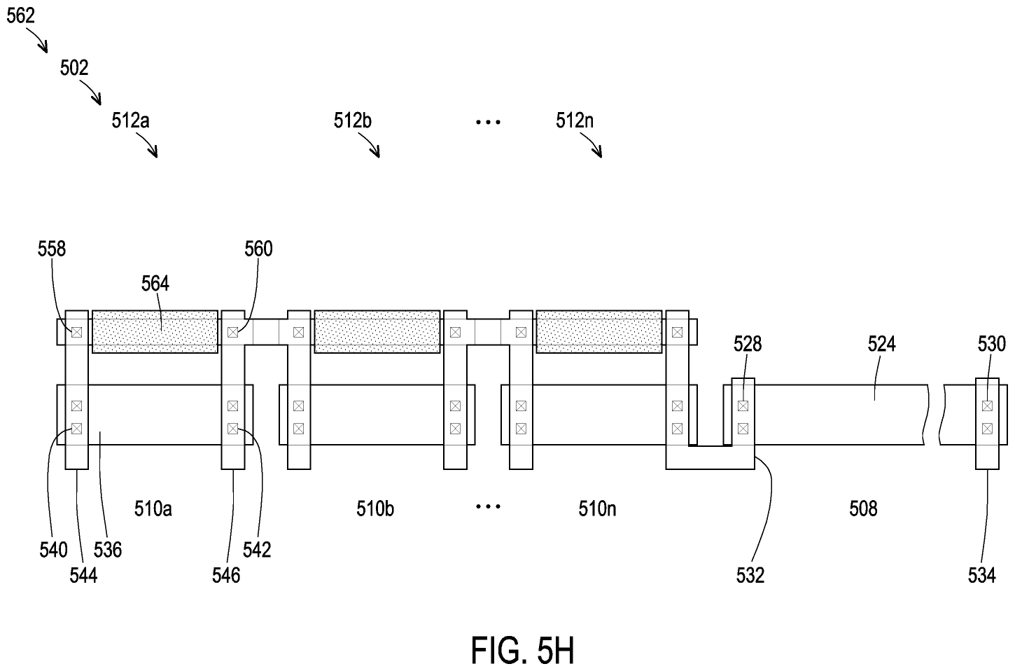

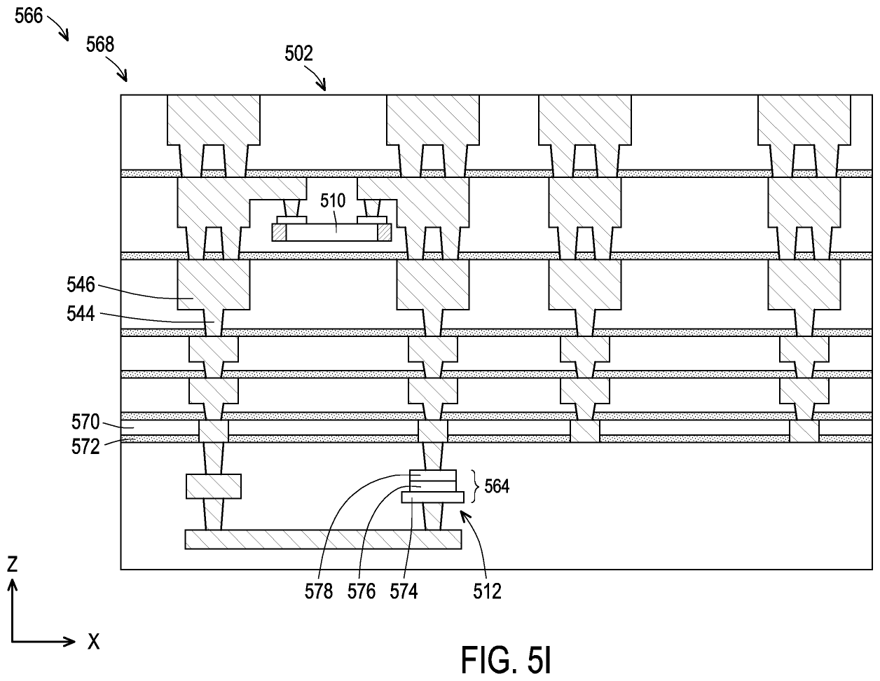

FIGS. 5A-5I are diagrams of example implementations of a tunable resistive sensor structure described herein. FIG. 5A illustrates an example 500 of a circuit implementation for a resistive sensor structure 502. The resistive sensor structure 502 is similar to the resistive sensor structure 202 in that the resistive sensor structure 502 includes one or more inputs 504a, 504b, one or more sensing terminals 506a, 506b, a main thin-film resistor 508, a plurality of selectable thin-film resistors 510a-510n that are electrically connected in series with each other and with the main thin-film resistor 508, and a plurality of control gates 512a-512n that are electrically connected in series with each other. Each of the control gates 512a-512n is electrically connected in parallel with a respective selectable thin-film resistor 510a-510n, and the control gates 512a-512n may be used to selectively activate or deactivate one or more of the selectable thin-film resistors 510a-510n in a similar manner as the resistive sensor structure 202. However, the control gates 512a-512n include programmable control gates (e.g., electrically programmable control gates) as opposed to transmission gates, as in the resistive sensor structure 502. FIGS. 5B-5I illustrate various example circuit and/or structural implementations of the programmable control gates. In some implementations, a resistive sensor structure may include a combination of programmable control gates and transmission gates for controlling the associated selectable thin-film resistors of the resistive sensor structure.

As shown in FIG. 5B, an example 514 of a circuit implementation of a control gate 512 includes an NMOS switch. The NMOS switch may include an NMOS transistor, and the gate of the NMOS transistor may be coupled to a control input for selectively switching the NMOS transistor between an on state and an off state. As shown in FIG. 5C, an example 516 of a circuit implementation of a control gate 512 includes a PMOS switch. The PMOS switch may include a PMOS transistor, and the gate of the PMOS transistor may be coupled to a control input for selectively switching the PMOS transistor between an on state and an off state. As shown in FIG. 5D, an example 518 of a circuit implementation of a control gate 512 includes a negative-positive-negative (NPN) switch. The NPN switch may include an NPN bipolar junction transistor (BJT), and the base of the NPN BJT may be coupled to a control input. As shown in FIG. 5E, an example 520 of a circuit implementation of a control gate 512 includes a positive-negative-positive (PNP) switch. The PNP switch may include a PNP BJT, and the base of the PNP BJT may be coupled to a control input.

FIG. 5F illustrates an example 522 of a structural implementation of the resistive sensor structure 502 in which the control gates 512a-512n of the resistive sensor structure 502 are implemented by floating gate transistors (e.g., flash memory transistors). The main thin-film resistor 508 includes an active region 524, an RPO layer 526, and contacts 528 and 530 that are respectively coupled with metallization layers 532 and 534. The selectable thin-film resistors 510a-510n each include an active region 536, an RPO layer 538, and contacts 540 and 542 that are respectively coupled with metallization layers 544 and 546.

Each of the control gates 512a-512n includes active regions 548a and 548b, word line structures 550a and 550b, control gate structures 552a and 552b, and an erase gate structure 554. The active regions 548a and 548b may be located on opposing sides of the erase gate structure 554. The word line structure 550a and the control gate structure 552a may be located above the active region 548a, and the word line structure 550b and the control gate structure 552b may be located above the active region 548b.

The control gate 512a may be electrically coupled with the selectable thin-film resistor 510a in parallel through the active region 536 of the selectable thin-film resistor 510a, and through the active regions 548a and 548b of the control gate 512a. The control gates 512b-512n may be respectively electrically coupled to the selectable thin-film resistors 510b-510n in a similar manner.

In the example 522 illustrated in FIG. 5F, the active regions 524, 536, 548a, and 548b may each be located in an oxide diffusion in a substrate of a semiconductor device. The word line structures 550a and 550b, the control gate structures 552a and 552b, and the erase gate structures 554 of the control gates 512a-512n may include polysilicon structures, metal structures, and/or another type of electrically conductive structures.

FIG. 5G illustrates an example 556 of a structural implementation of the resistive sensor structure 502 in which the control gates 512a-512n of the resistive sensor structure 502 are implemented by floating gate transistors. The example 556 is similar to the example 522 in FIG. 5F, except that the main thin-film resistor 508 and the selectable thin-film resistors 510a-510n in the example 556 of the structural implementation of the resistive sensor structure 502 may be included in an interconnect structure or interconnect region (e.g., a backend region) of a semiconductor device. Thus, the active region 524 of the main thin-film resistor 508 and the active regions 536 of the selectable thin-film resistors 510a-510n may include polysilicon resistive layers in the example 556 of the structural implementation of the resistive sensor structure 502. Accordingly, the RPO layer 526 may be omitted. The main thin-film resistor 508, the selectable thin-film resistors 510a-510n, and the control gates 512a-512n may be interconnected by the metallization layers 532, 534, 544, and 546 in the interconnect structure of the semiconductor device. For example, the main thin-film resistor 508 may be electrically connected in series with the selectable thin-film resistor 510n through metallization layers 532 and 546, the selectable thin-film resistor 510n may be electrically connected in series with the selectable thin-film resistor 510b through metallization layers 544 and 546, and so on. As another example, the selectable thin-film resistor 510a may be electrically connected in parallel with the control gate 512a through metallization layers 544 and 546. The control gates 512a-512n may be electrically connected in series through metallization layers 544 and 546 as well. The control gates 512a-512n may be electrically connected to the metallization layers 544 through contacts 558, and the control gates 512a-512n may be electrically connected to the metallization layers 546 through contacts 560.

FIG. 5H illustrates an example 562 of a structural implementation of the resistive sensor structure 502. The example 562 of the structural implementation of the resistive sensor structure 502 is similar to the example 556 of the structural implementation of the resistive sensor structure 502, except that the control gates 512a-512n of the resistive sensor structure 502 are implemented by resistive random access memory (RRAM) cells 564 in the example 562 of the structural implementation of the resistive sensor structure 502.

FIG. 5I illustrates an example 566 of a structural implementation of a semiconductor device 568 in which a resistive sensor structure 502 may be included. The semiconductor device 568 may include a plurality of dielectric layers 570 (similar to dielectric layers 272) and a plurality of ESLs 572 (similar to ESLS 274) in which the resistive sensor structure 502 may be included. A selectable thin-film resistor 510 of the resistive sensor structure 502 may be electrically coupled with metallization layers 544 and 546 that extend through the dielectric layers 570 and ESLs 572. The metallization layers 544 and 546 electrically connect the selectable thin-film resistor 510 with a control gate 512, which may be implemented as an RRAM structure 564 in the example 562. The RRAM structure 564 includes a bottom electrode (BE) 574, a switching layer 576 on the bottom electrode 574, and a top electrode (TE) 578 on the switching layer 576. A voltage or another type of electrical input may be applied across the switching layer 576 to modify the resistance of the switching layer 576, thereby selectively activating or deactivating the selectable thin-film resistor 510.

In some implementations, the switching layer 576 includes a transition metal oxide (TMO) such as hafnium oxide (HfOₓ), titanium oxide (TiOₓ), and/or tantalum oxide (TaN). In some implementations, the switching layer 576 includes a chalcogenide such as silver selenide (AgSe) and/or copper sulfide (CuS), among other examples. In some implementations, the switching layer 576 includes another type of material.

As indicated above, FIGS. 5A-5I are provided as examples. Other examples may differ from what is described with regard to FIGS. 5A-5I.

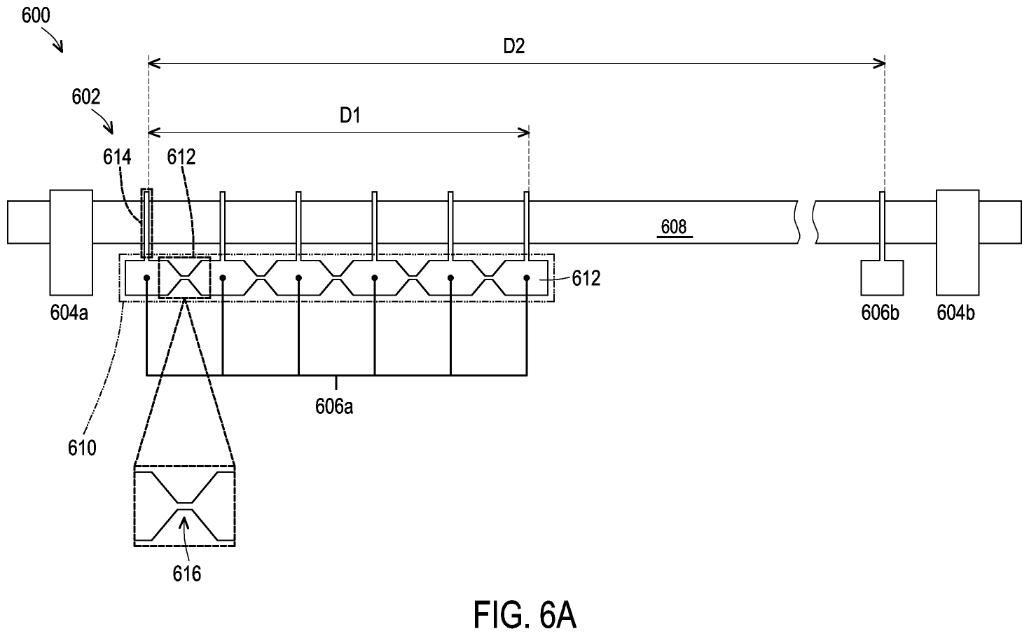

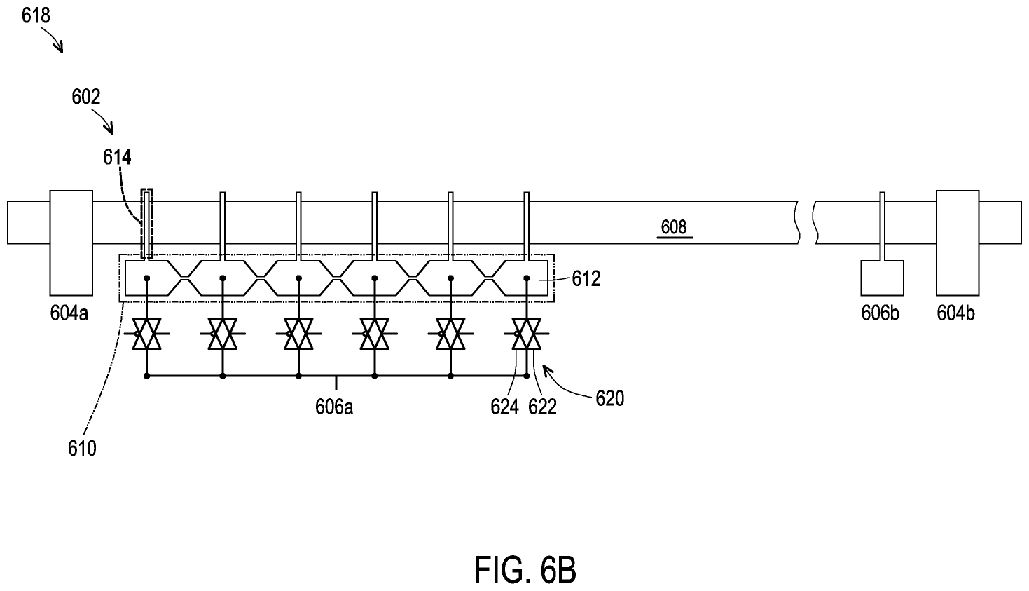

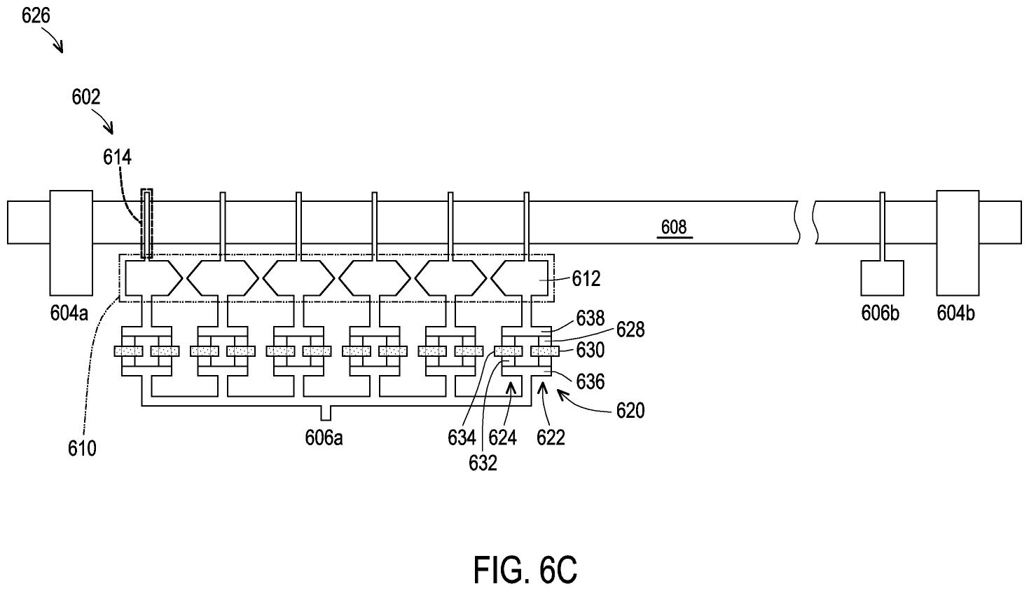

FIGS. 6A-6C are diagrams of example implementations of a tunable resistive sensor structure described herein. FIG. 6A illustrates an example 600 of a structural implementation for a resistive sensor structure 602. The resistive sensor structure 602 includes one or more inputs 604a, 604b, and one or more sensing terminals 606a, 606b. The resistive sensor structure 602 may be configured as a current meter (e.g., a sensor that is configured to sense a magnitude of a current on the inputs 604a, 604b based on a resistance of the resistive sensor structure 602), a thermal sensor (e.g., a sensor that is configured to sense a temperature based on a current on the inputs 604a, 604b), and/or another type of resistance-based sensor.

As shown in FIG. 6A, the resistive sensor structure 602 includes a main thin-film resistor 608 and a resistance trimming structure 610 electrically coupled with the main thin-film resistor 608. The resistance trimming structure 610 includes a plurality of resistance trimming pads 612 that are electrically connected in series. Each of the resistance trimming pads 612 are electrically coupled with the main thin-film resistor 608 through an electrically conductive sensing line 614. A length of the resistance trimming structure 610 (indicated in FIG. 6A as dimension D1) may be less than a length of the main thin-film resistor 608 (indicated in FIG. 6B as dimension D2).

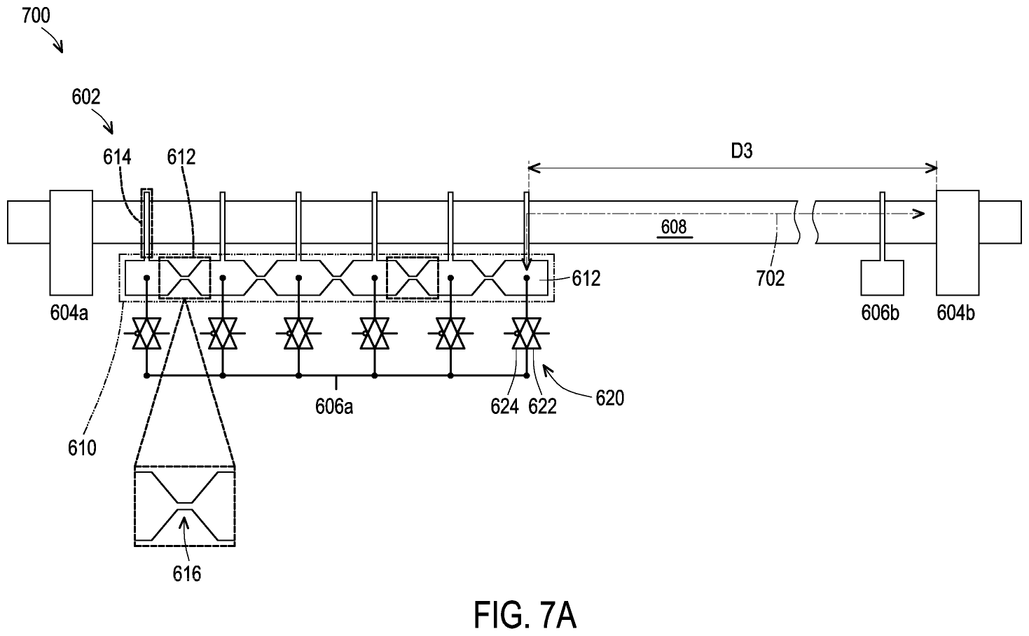

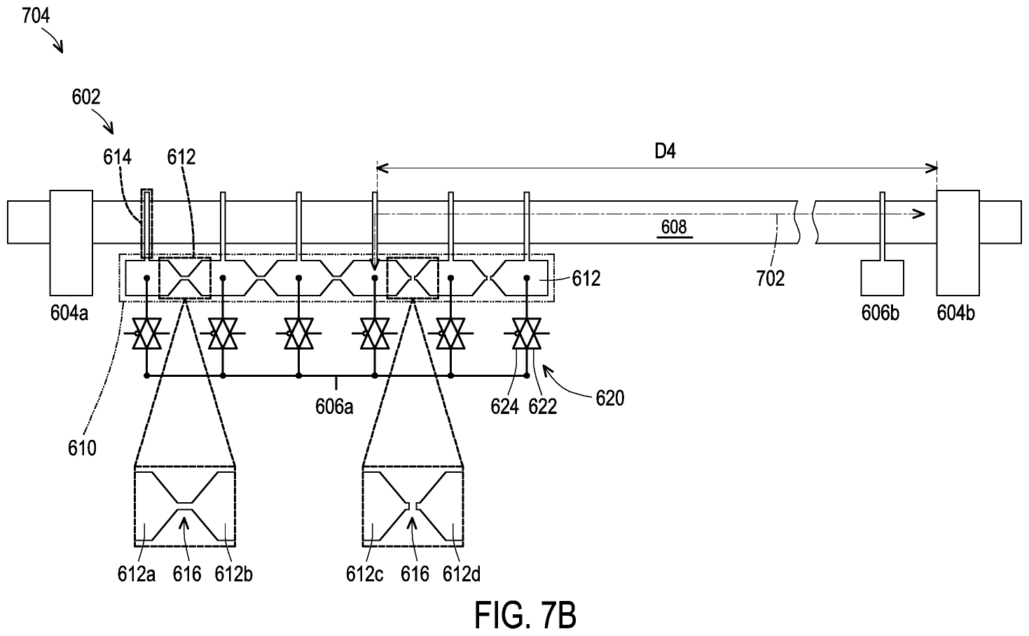

The resistance trimming pads 612 can be used to tune or trim the overall resistance (or overall TCR) of the resistive sensor structure 602. In particular, the electrical continuity between the resistance trimming pads 612 can be modified to modify the effective length of the resistive sensor structure 602. Burn-out regions 616 are located between adjacent resistance trimming pads 612. The burn-out regions 616 provide electrical continuity between adjacent resistance trimming pads 612 when the burn-out regions 616 are intact. An input current may be provided through the sensing terminal 606a to cause one or more of the burn-out regions 616 to be burned out or damaged, which results in an electrical disconnect between adjacent resistance trimming pads 612. Breaking the electrical continuity between two or more resistance trimming pads 612 may increase the effective length of the resistive sensor structure 602 in that electrical current propagates a longer distance through the main thin-film resistor 608 between the inputs 604a, 604b and the sensing terminals 606a, 606b than if all of the resistance trimming pads 612 were electrically connected. Examples of current flow paths in the resistive sensor structure 602 are illustrated and described in connection with FIGS. 7A and 7B.

FIG. 6B illustrates an example 618 of the resistive sensor structure 602 in which control gates 620 are included and electrically connected with the resistance trimming pads 612. The control gates 620 can be used to selectively provide the input current to particular ones of the resistance trimming pads 612 to cause the burn-out regions 616 between adjacent resistance trimming pads 612 to be burned out and disconnected. In the example 618, the control gates 620 are implemented as transmission gates that each include an NMOS transistor 622 and a PMOS transistor 624.

FIG. 6C illustrates an example 626 of a structural implementation of the control gates 620 of the resistive sensor structure 602. As shown in FIG. 6C, a control gate 620 may include an NMOS transistor 622 and a PMOS transistor 624. An NMOS transistor 622 may be similar to an NMOS transistor 214 in that an NMOS transistor 622 may include an active region 628 and a gate structure 630. A PMOS transistor 624 may be similar to a PMOS transistor 216 in that a PMOS transistor 624 may include an active region 632 and a gate structure 634. The NMOS transistors 622 and the PMOS transistors 624 may be electrically coupled with the sensing terminal 606a by metallization layers 636, and may be electrically coupled with the resistance trimming pads 612 by metallization layers 638.

As indicated above, FIGS. 6A-6C are provided as examples. Other examples may differ from what is described with regard to FIGS. 6A-6C.

FIGS. 7A and 7B are diagrams of example operational configurations for the resistive sensor structure 602 described herein. FIG. 7A illustrates an example configuration 700 in which the burn-out regions 616 between the resistance trimming pads 612 are intact. Thus, the effective length (indicated in FIG. 7A as dimension D3) of the resistive sensor structure 602 corresponds to a distance of a current flow path 702 between one or more of the inputs 604a, 604b and the sensing terminal 606a.

FIG. 7B illustrates an example configuration 704 in which the burn-out regions 616 between two or more resistance trimming pads 612 (e.g., between resistance trimming pads 612a and 612b) are intact, and the burn-out regions 616 between two or more resistance trimming pads 612 (e.g., between resistance trimming pads 612c and 612d) are broken. Thus, the effective length (indicated in FIG. 7B as dimension D4) of the resistive sensor structure 602 may be greater than the effective length in the example configuration 700, resulting in a greater overall resistance for the resistive sensor structure 602.

As indicated above, FIGS. 7A and 7B are provided as examples. Other examples may differ from what is described with regard to FIGS. 7A and 7B.

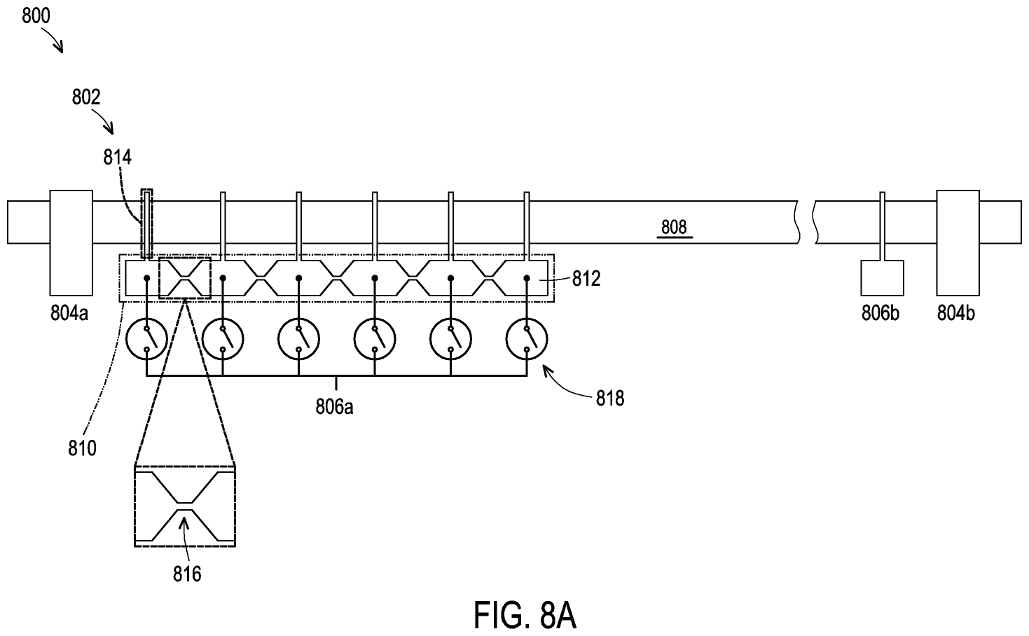

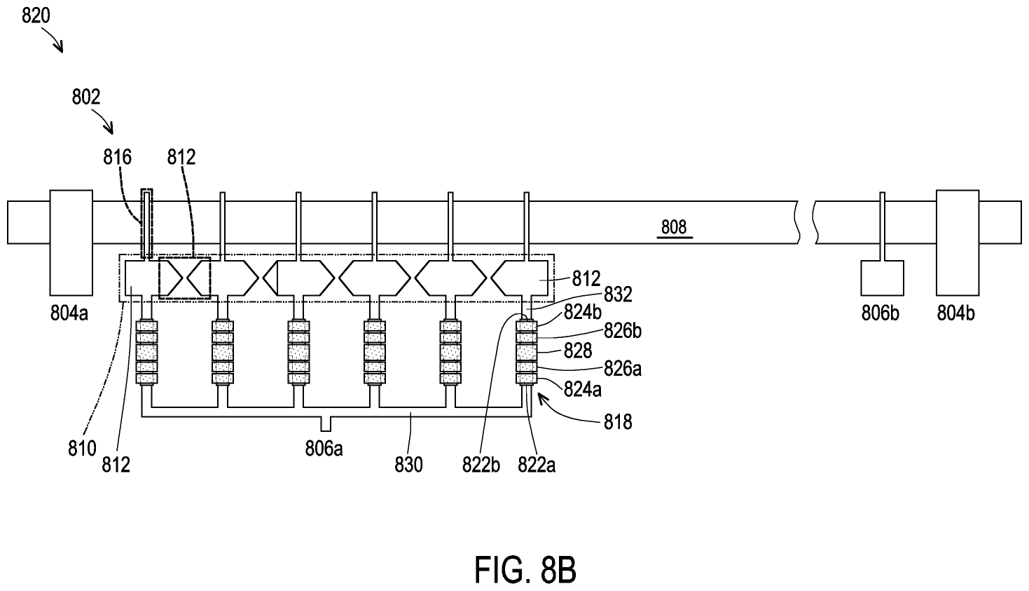

FIGS. 8A and 8B are diagrams of example implementations of a tunable resistive sensor structure described herein. FIG. 8A illustrates an example 800 of an implementation for a resistive sensor structure 802. The resistive sensor structure 802 is similar to the resistive sensor structure 602, and includes one or more inputs 804a, 804b, one or more sensing terminals 806a, 806b, a main thin-film resistor 808, a resistance trimming structure 810 that includes a plurality of resistance trimming pads 812 coupled with the main thin-film resistor 808 through electrically conductive sensing lines 814, and burn-out regions 816 between adjacent resistance trimming pads 812. However, control gates 818 of the resistive sensor structure 802 are different from the control gates 612 of the resistive sensor structure 602 in that the control gates 818 include programmable gate structures similar to the control gates 512a-512n of the resistive sensor structure 502. The control gates 818 may be implemented by one or more examples of programmable control gates illustrated and described in connection with FIGS. 5A-5I.

FIG. 8B illustrates an example 820 of a structural implementation of the control gates 818 of the resistive sensor structure 802. As shown in FIG. 8B, a control gate 818 may include a floating gate transistor structure that includes active regions 822a and 822b, word line structures 824a and 824b, control gate structures 826a and 826b, and an erase gate structure 828. The control gates 818 may be electrically coupled with the sensing terminal 806a by metallization layers 830, and may be electrically coupled with the resistance trimming pads 812 by metallization layers 832.

As indicated above, FIGS. 8A and 8B are provided as examples. Other examples may differ from what is described with regard to FIGS. 8A and 8B.

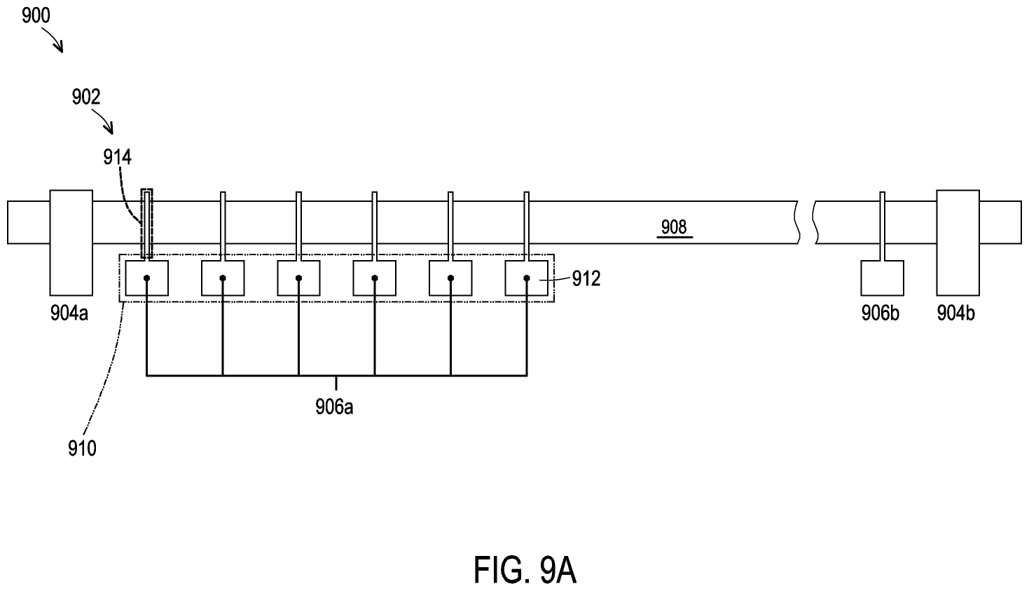

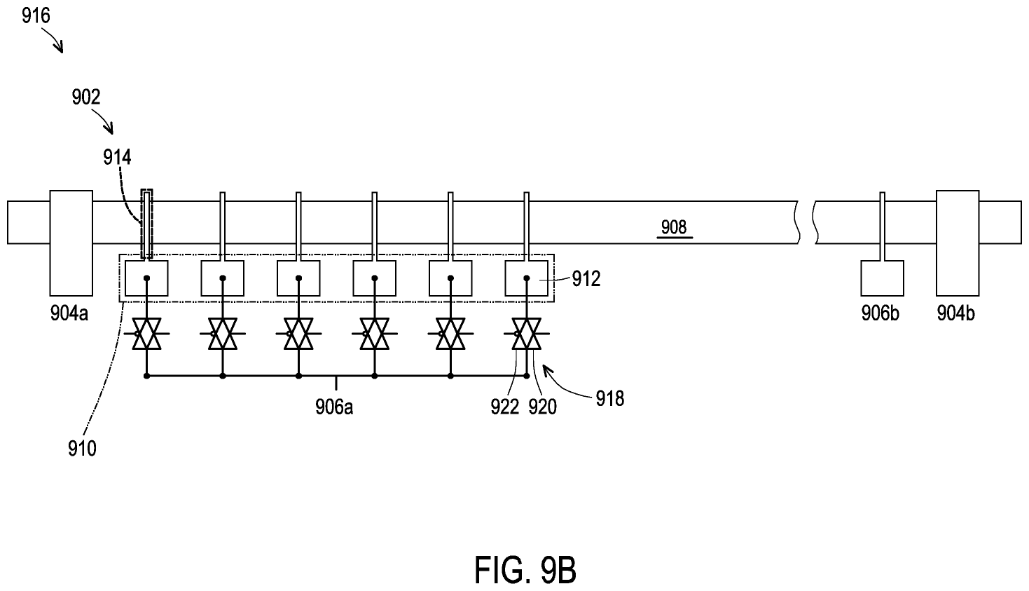

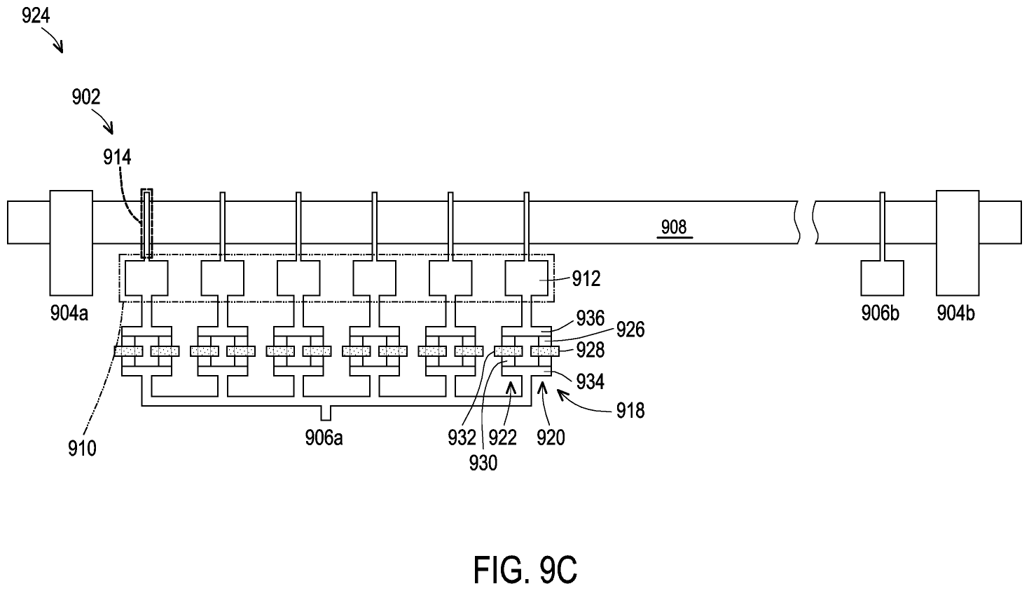

FIGS. 9A-9C are diagrams of example implementations of a tunable resistive sensor structure described herein. FIG. 9A illustrates an example 900 of a structural implementation for a resistive sensor structure 902. The resistive sensor structure 902 is similar to the resistive sensor structure 602, and includes one or more inputs 904a, 904b, one or more sensing terminals 906a, 906b, a main thin-film resistor 908, a resistance trimming structure 910 that includes a plurality of resistance trimming pads 912 coupled with the main thin-film resistor 908 through electrically conductive sensing lines 914. However, burn-out regions between adjacent resistance trimming pads 912 are omitted in the resistive sensor structure 902.

As shown in an example 916 in FIG. 9B, the electrical conductivity between the resistance trimming pads 912 and the sensing terminal 906a is directly controlled by control gates 918. Each of the resistance trimming pads 912 may be electrically coupled with an associated control gate 918 that is implemented as a transmission gate including an NMOS transistor 920 and a PMOS transistor 922, similar to the control gates 212a-212n. Instead of using the control gates 918 to selectively damage burn-out regions to control the effective length of the resistive sensor structure 902, a control gate 918 may be activated to enable an electrical current to flow from the main thin-film resistor 908 to the sensing terminal 906a through the associated resistance trimming pad 912 to control the effective length of the resistive sensor structure 902. Accordingly, the resistance trimming structure 910 is reprogrammable, enabling the overall resistance and/or the overall TCR of the resistive sensor structure 902 to be multiple-time programmable.

FIG. 9C illustrates an example 924 of a structural implementation of the control gates 918 of the resistive sensor structure 902. As shown in FIG. 9C, a control gate 918 may include an NMOS transistor 920 and a PMOS transistor 922. An NMOS transistor 920 may be similar to an NMOS transistor 214 in that an NMOS transistor 920 may include an active region 926 and a gate structure 928. A PMOS transistor 922 may be similar to a PMOS transistor 216 in that a PMOS transistor 922 may include an active region 930 and a gate structure 932. The NMOS transistors 920 and the PMOS transistors 922 may be electrically coupled with the sensing terminal 906a by metallization layers 934, and may be electrically coupled with the resistance trimming pads 912 by metallization layers 936.

As indicated above, FIGS. 9A-9C are provided as examples. Other examples may differ from what is described with regard to FIGS. 9A-9C.

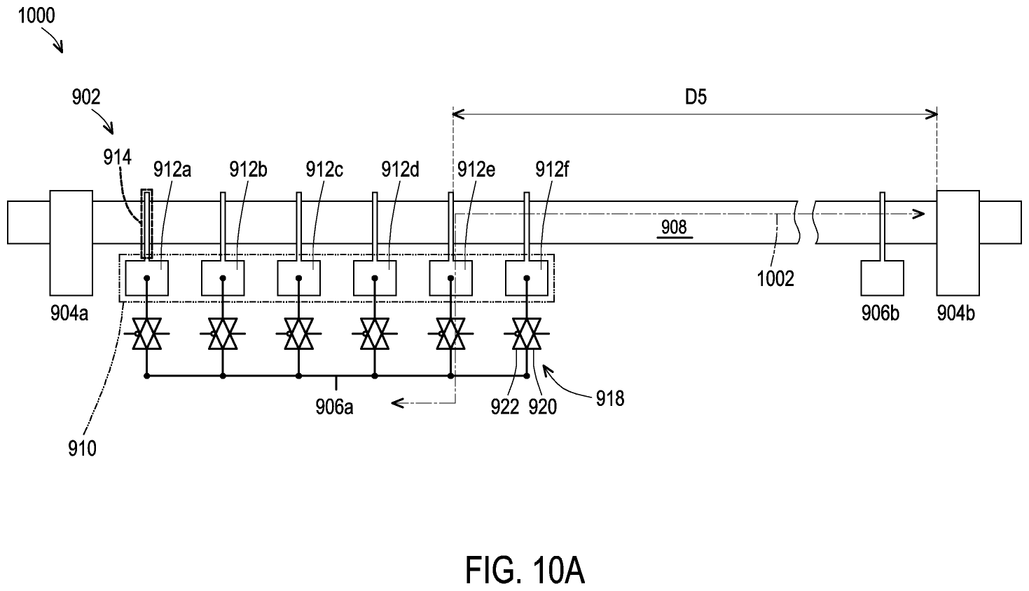

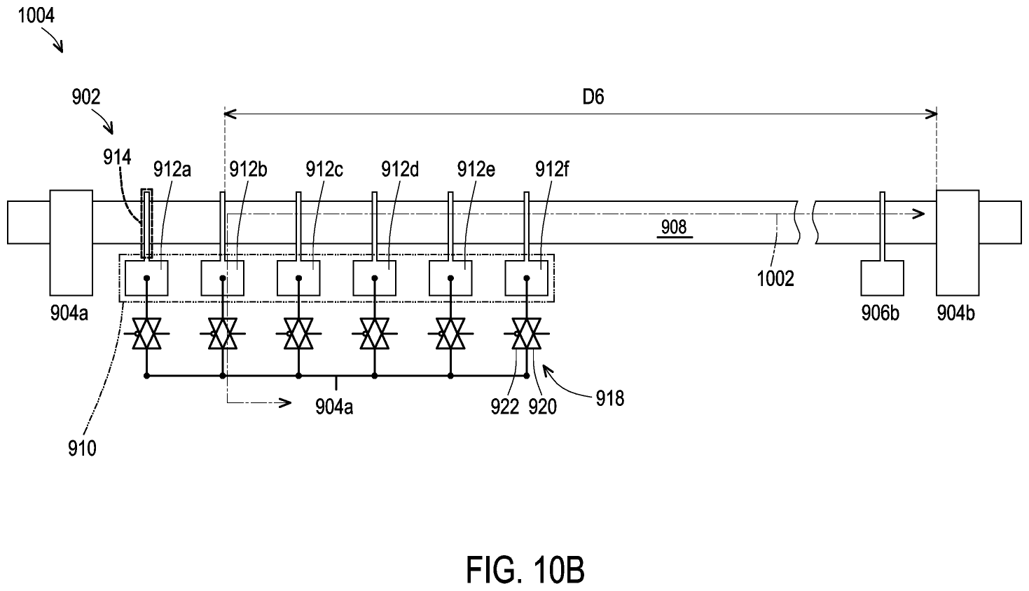

FIGS. 10A and 10B are diagrams of example operational configurations for the resistive sensor structure 902 described herein. FIG. 10A illustrates an example configuration 1000 in which a resistance trimming pad 912e (among resistance trimming pads 912a-912f) is activated by an associated control gate 918. Thus, the effective length (indicated in FIG. 10A as dimension D5) of the resistive sensor structure 902 corresponds to a distance of a current flow path 1002 between one or more of the inputs 904a, 904b and the sensing terminal 906a through the resistance trimming pad 912c.

FIG. 10B illustrates an example configuration 1004 in which a resistance trimming pad 912b (among resistance trimming pads 912a-912f) is activated by an associated control gate 918. Thus, the effective length (indicated in FIG. 10B as dimension D6) of the resistive sensor structure 902 corresponds to a distance of a current flow path 1002 between one or more of the inputs 904a, 904b and the sensing terminal 906a through the resistance trimming pad 912b, which may be greater than the effective length of the resistive sensor structure 902 in the example configuration 1000.

As indicated above, FIGS. 10A and 10B are provided as examples. Other examples may differ from what is described with regard to FIGS. 10A and 10B.

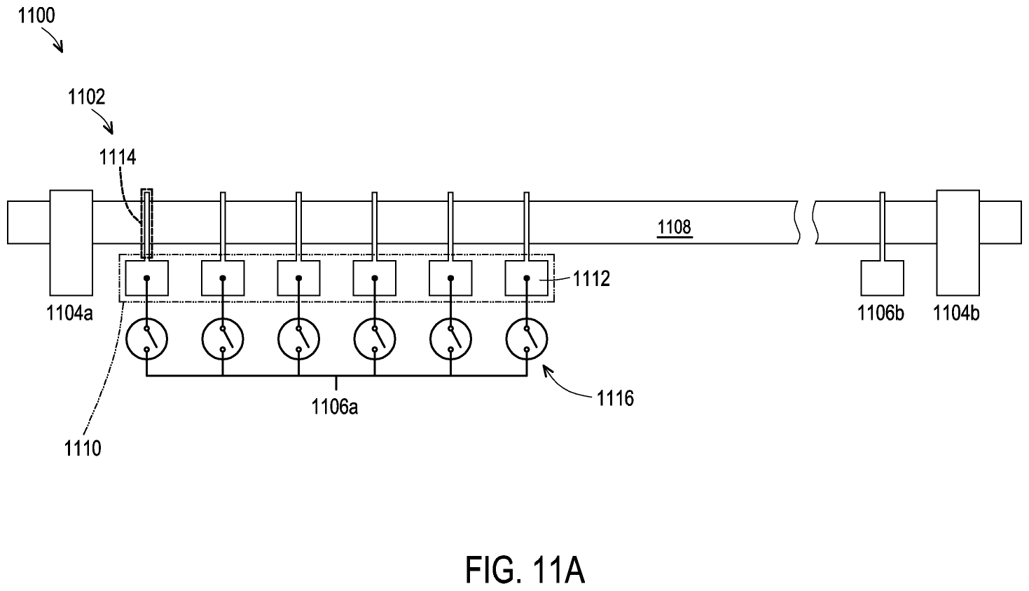

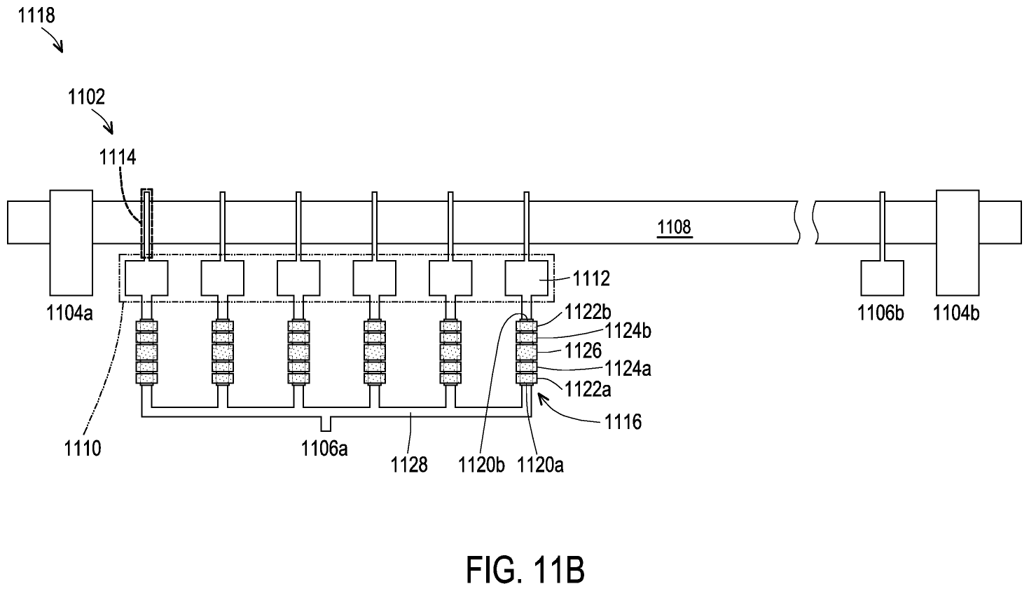

FIGS. 11A and 11B are diagrams of example implementations of a tunable resistive sensor structure described herein. FIG. 11A illustrates an example 1100 of an implementation for a resistive sensor structure 1102. The resistive sensor structure 1102 is similar to the resistive sensor structure 902, and includes one or more inputs 1104a, 1104b, one or more sensing terminals 1106a, 1106b, a main thin-film resistor 1108, a resistance trimming structure 1110 that includes a plurality of resistance trimming pads 1112 coupled with the main thin-film resistor 1108 through electrically conductive sensing lines 1114, and control gates 1116 coupled with the resistance trimming pads 1112. However, the control gates 1116 of the resistive sensor structure 1102 are different from the control gates 918 of the resistive sensor structure 902 in that the control gates 1116 include programmable gate structures similar to the control gates 512a-512n of the resistive sensor structure 502. The control gates 1116 may be implemented by one or more examples of programmable control gates illustrated and described in connection with FIGS. 5A-5I.

FIG. 11B illustrates an example 1118 of a structural implementation of the control gates 1116 of the resistive sensor structure 1102. As shown in FIG. 11B, a control gate 1116 may include a floating gate transistor structure that includes active regions 1120a and 1120b, word line structures 1122a and 1122b, control gate structures 1124a and 1124b, and an erase gate structure 1126. The control gates 1116 may be electrically coupled with the sensing terminal 1106a by metallization layers 1128, and may be electrically coupled with the resistance trimming pads 1112 by metallization layers 1130.

As indicated above, FIGS. 11A and 11B are provided as examples. Other examples may differ from what is described with regard to FIGS. 11A and 11B.

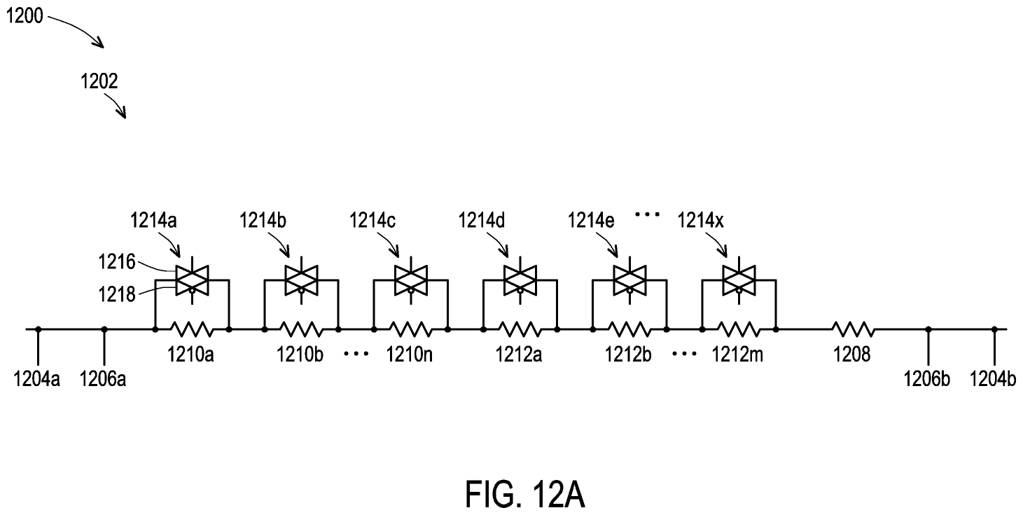

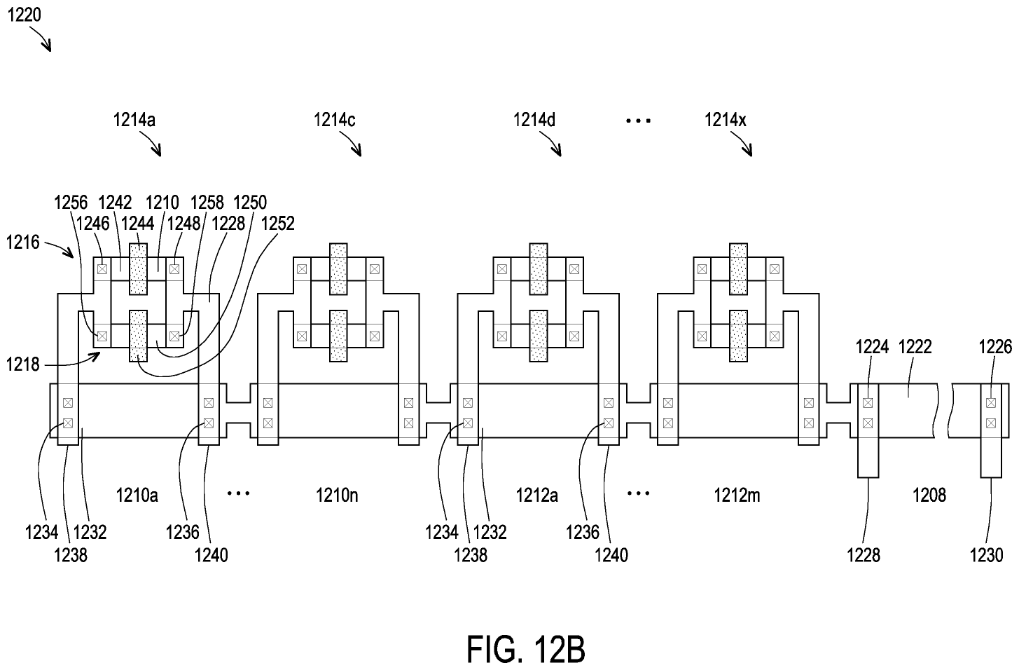

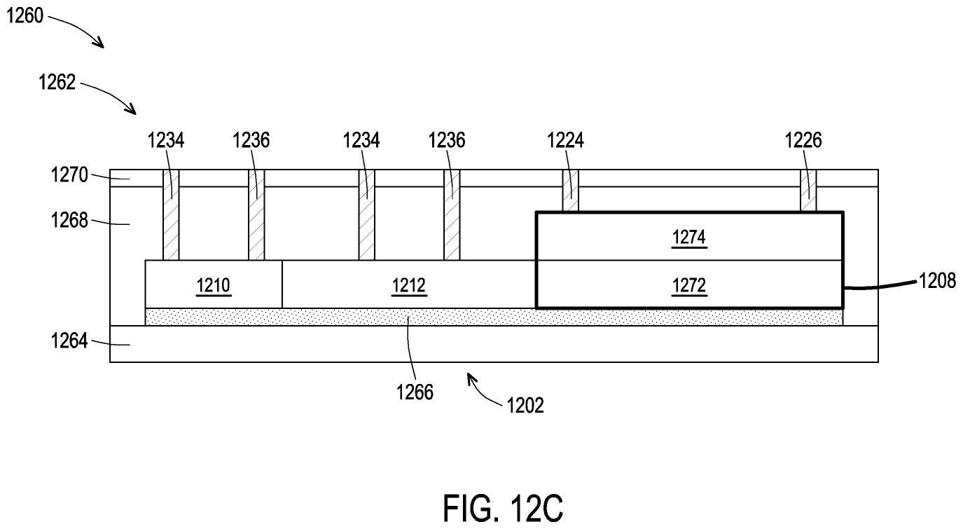

FIGS. 12A-12C are diagrams of example implementations of a tunable resistive sensor structure described herein. FIG. 12A illustrates an example 1200 of a circuit implementation for a resistive sensor structure 502. The resistive sensor structure 1202 is similar to the resistive sensor structure 1202 in that the resistive sensor structure 1202 includes one or more inputs 1204a, 1204b, one or more sensing terminals 1206a, 1206b, a main thin-film resistor 1208, a plurality of selectable thin-film resistors 1210a-1210n and 1212a-1212m that are electrically connected in series with each other and with the main thin-film resistor 1208, and a plurality of control gates 1214a-1214x that are electrically connected in series with each other. Each of the control gates 1214a-1214x is electrically connected in parallel with a respective selectable thin-film resistor, and the control gates 1214a-1214x may be used to selectively activate or deactivate one or more of the selectable thin-film resistors in a similar manner as the resistive sensor structure 202. Moreover, the control gates may be implemented as transmission gates that each include an NMOS transistor 1216 (e.g., similar to an NMOS transistor 214) electrically coupled in parallel with a PMOS transistor 1218 (e.g., similar to a PMOS transistor 216).

However, the selectable thin-film resistors 1210a-1210n may affect the overall TCR of the resistive sensor structure 1202 differently than the selectable thin-film resistors 1212a-1212m. In particular, a selectable thin-film resistor 1210a-1210n, when activated by an associated control gate 1214a-1214x, may increase the overall TCR of the resistive sensor structure 1202, whereas a selectable thin-film resistor 1212a-1212m, when activated by an associated control gate 1214a-1214x, may decrease the overall TCR of the resistive sensor structure 1202. The greater the quantity of the selectable thin-film resistors 1210a-1210n that are activated, the greater the increase in overall TCR of the resistive sensor structure 1202. The greater the quantity of the selectable thin-film resistors 1212a-1212m that are activated, the greater the decrease in overall TCR of the resistive sensor structure 1202.

FIG. 12B illustrates an example 1220 of a structural implementation of the resistive sensor structure 1202. As shown in FIG. 12B, the example 1220 of the structural implementation of the resistive sensor structure 1202 may be similar to the example 218 of the structural implementation of the resistive sensor structure 202. For example, the main thin-film resistor 1208 includes an active region 1222, contacts 1224 and 1226, and metallization layers 1228 and 1230, respectively similar to the active region 220, contacts 224 and 226, and metallization layers 228 and 230 of the main thin-film resistor 208. The selectable thin-film resistors 1210a-1210n and 1212a-1212m may each include an active region 1232, contacts 1234 and 1236, and metallization layers 1238 and 1240, respectively similar to the active region 232, contacts 236 and 238, and metallization layers 240 and 242 of the selectable thin-film resistors 210a-210n. The control gates 1214 each include an NMOS transistor 1216 that includes an active region 1242, a gate structure 1244, contacts 1246 and 1248; and a PMOS transistor 1218 that includes an active region 1250, a gate structure 1252, and contacts 1256 and 1258.

However, the active regions 1232 of the selectable thin-film resistors 1210a-1210n include one or more TCR-increasing materials. Examples of TCR-increasing materials include platinum (Pt), titanium nitride (TiN), ruthenium oxide (RuOₓ), tantalum (Ta), and/or nickel chromium (NiCr), among other examples. Conversely, the active regions 1232 of the selectable thin-film resistors 1212a-1212m include one or more TCR-reducing materials. Examples of TCR-reducing materials include tantalum nitride (TaN), nickel-chromium-aluminum (NiCrAl) alloys, copper-nickel (CuNi) alloys, and/or binary and ternary oxide such as indium tin oxide (ITO) and/or zinc oxide doped with aluminum (AZO), among other examples.

The active regions 1232 of the selectable thin-film resistors 1210a-1210n are electrically connected in series. The active regions 1232 of the selectable thin-film resistors 1212a-1212m are electrically connected in series. The active region 1222 of the main thin-film resistor 1208 is electrically coupled in series with the active regions 1232 of the selectable thin-film resistors 1210a-1210n and of the selectable thin-film resistors 1212a-1212m. Each of a first subset of the control gates 1214a-1214x is electrically coupled in parallel with a corresponding one of the selectable thin-film resistors 1210a-1210n. Each of a second subset of the control gates 1214a-1214x is electrically coupled in parallel with a corresponding one of the selectable thin-film resistors 1212a-1212m. The control gates 1214a-1214x are also electrically coupled in series with the main thin-film resistor 1208.

FIG. 12C illustrates an example 1260 of a structural implementation of a semiconductor device 1262 in which a resistive sensor structure 1202 may be included. The semiconductor device 1262 may include a substrate 1264 and a plurality of dielectric layers 1266, 1268, and 1270. The resistive sensor structure 1202 may include the main thin-film resistor 1208, which may include one or more resistive sections 1272 and 1274 that are vertically arranged in the semiconductor device 1262. In some implementations, the section 1272 is a TCR-reducing section and the section 1274 is a TCR-increasing section. The main thin-film resistor 1208 is electrically coupled with contacts 1224 and 1226.

A selectable thin-film resistor 1210 includes a TCR-increasing material, and is electrically coupled with a set of contacts 1234 and 1236. A selectable thin-film resistor 1212 may be located between the selectable thin-film resistor 1210 and the main thin-film resistor 1208, and may include a TCR-reducing material. The selectable thin-film resistor 1212 may be electrically coupled with another set of contacts 1234 and 1236.

As indicated above, FIGS. 12A-12C are provided as examples. Other examples may differ from what is described with regard to FIGS. 12A-12C.

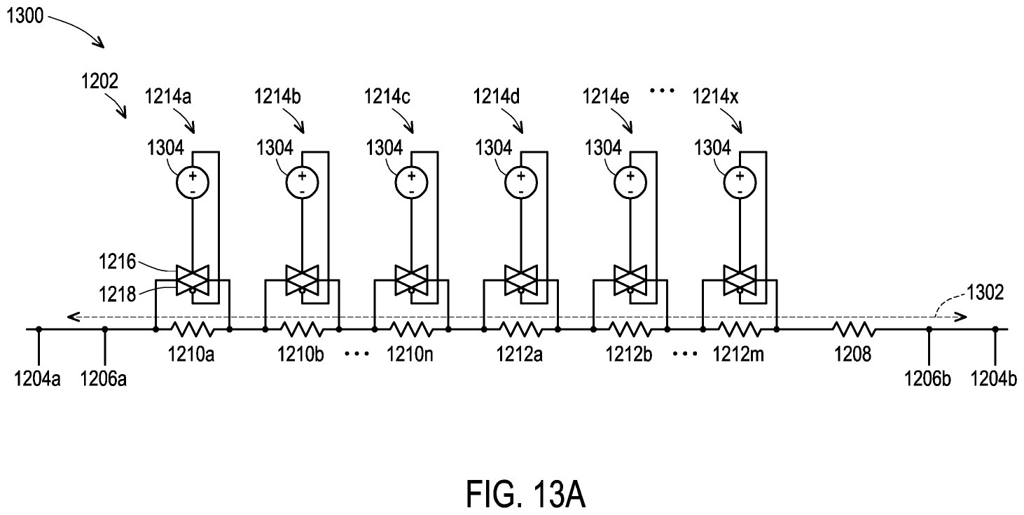

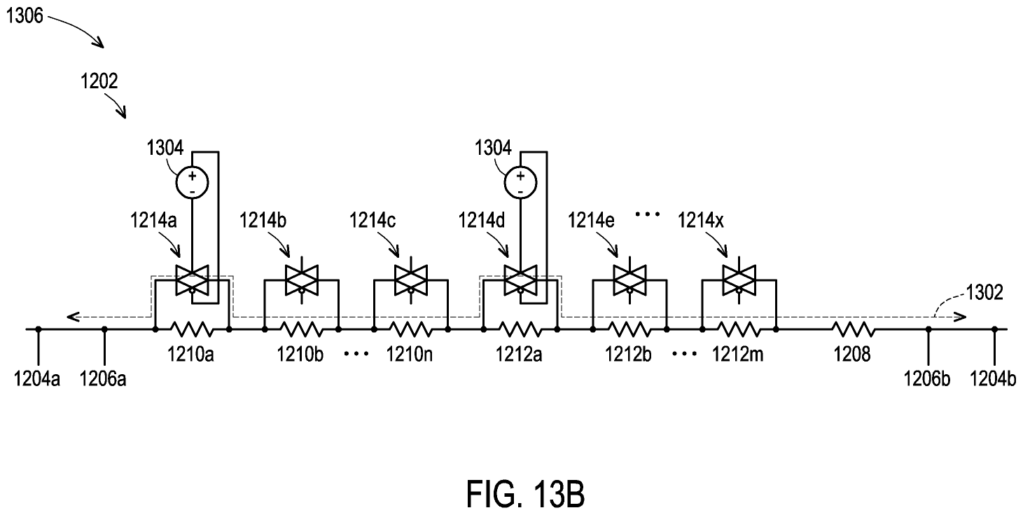

FIGS. 13A and 13B are diagrams of example operational configurations for the resistive sensor structure 1202 described herein. FIG. 13A illustrates an example configuration 1300 in which the control gates 1214a-1214x of the resistive sensor structure 1202 are all in an on state, and an associated current flow path 1302 through the resistive sensor structure 1202. The control gates 1214a-1214x may be switched to the on state by applying voltage inputs 1304 to the control gates 1214a-1214x.

When the control gates 1214a-1214x are in the on state, the selectable thin-film resistors 1210a-1210n and the selectable thin-film resistors 1212a-1212m of the resistive sensor structure 1202 are deactivated and bypassed. Thus, the current flow path 1302 through the resistive sensor structure 1202 is through the main thin-film resistor 1208 and through the control gates 1214a-1214x. Thus, the selectable thin-film resistors 1210a-1210n and the selectable thin-film resistors 1212a-1212m do not contribute to the overall TCR of the resistive sensor structure 1202.

FIG. 13B illustrates an example configuration 1306 in which only the control gates 1214a and 1214d of the resistive sensor structure 1202 are all in the on state. Thus, the selectable thin-film resistors 1210b-1210n of the resistive sensor structure 1202 are activated, and the selectable thin-film resistors 1212b-1212m of the resistive sensor structure 1202 are activated. Thus, the current flow path 1302 through the selectable thin-film resistors 1210b-1210n and through the selectable thin-film resistors 1212b-1212m, in addition to the main thin-film resistor 208. Accordingly, the overall TCR of the resistive sensor structure 1202 corresponds to the TCR of the main thin-film resistor 1208, as modified by the TCRs of the selectable thin-film resistors 1210b-1210n and the selectable thin-film resistors 1212b-1212m.

As indicated above, FIGS. 13A and 13B are provided as examples. Other examples may differ from what is described with regard to FIGS. 13A and 13B.

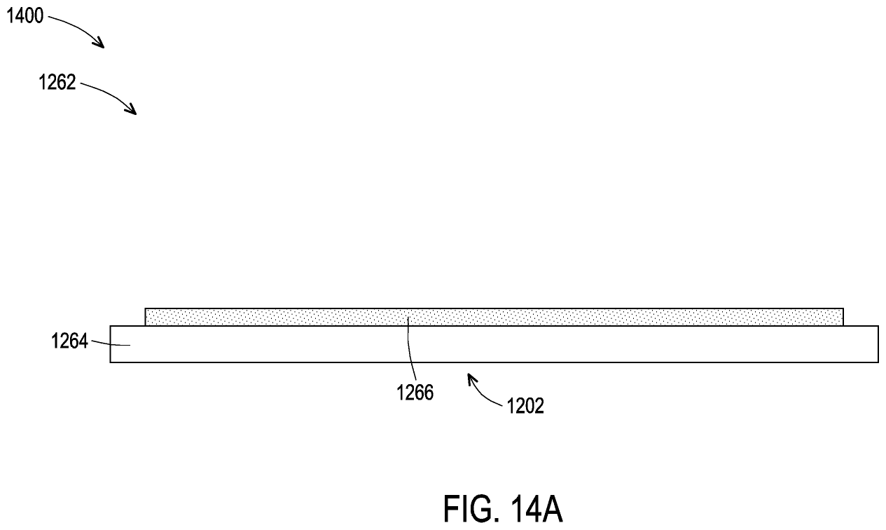

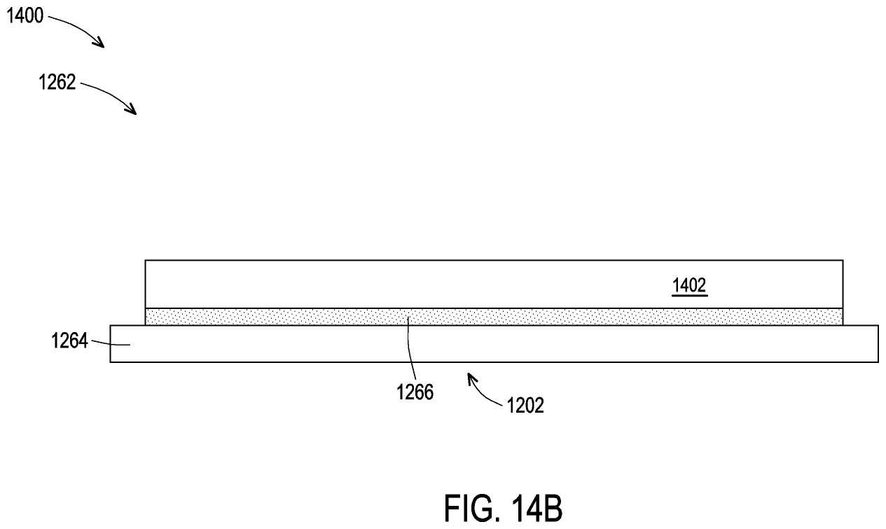

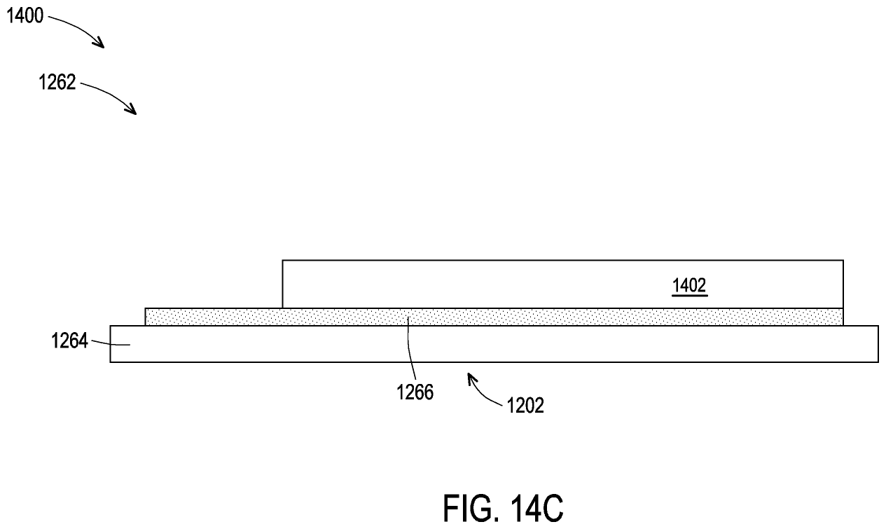

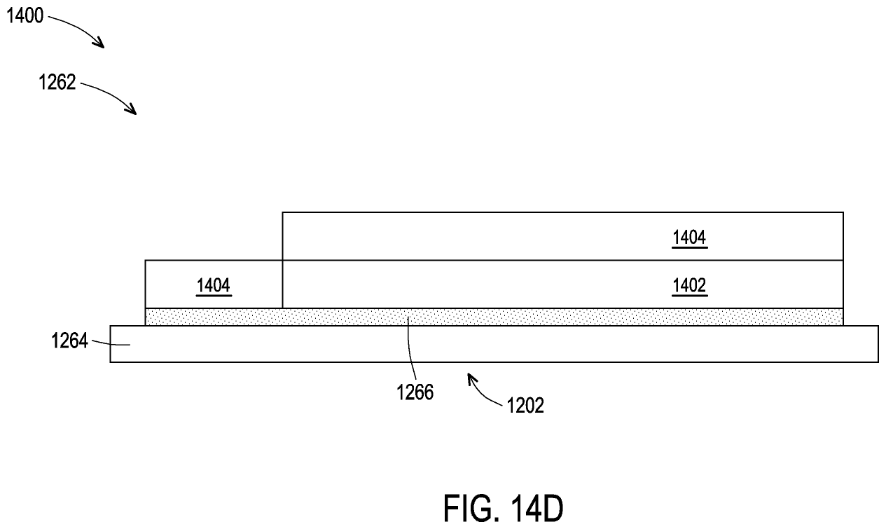

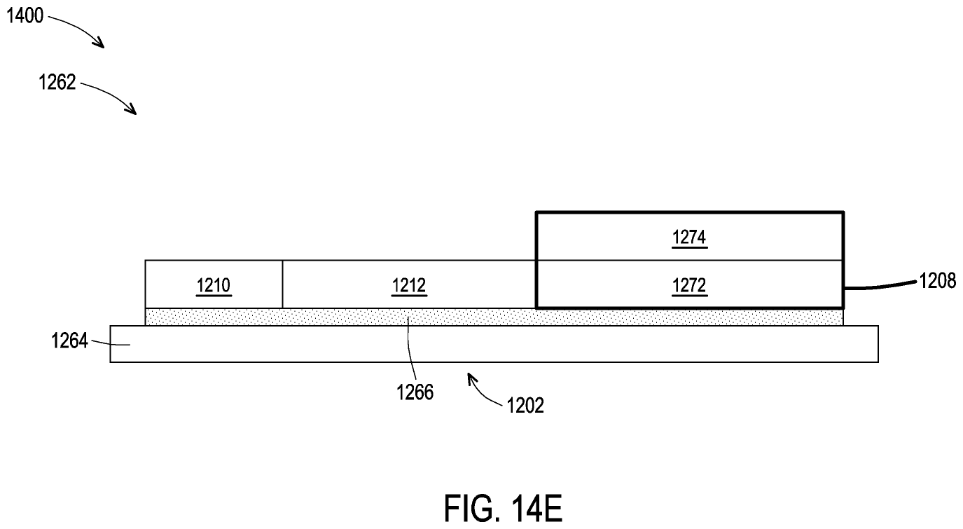

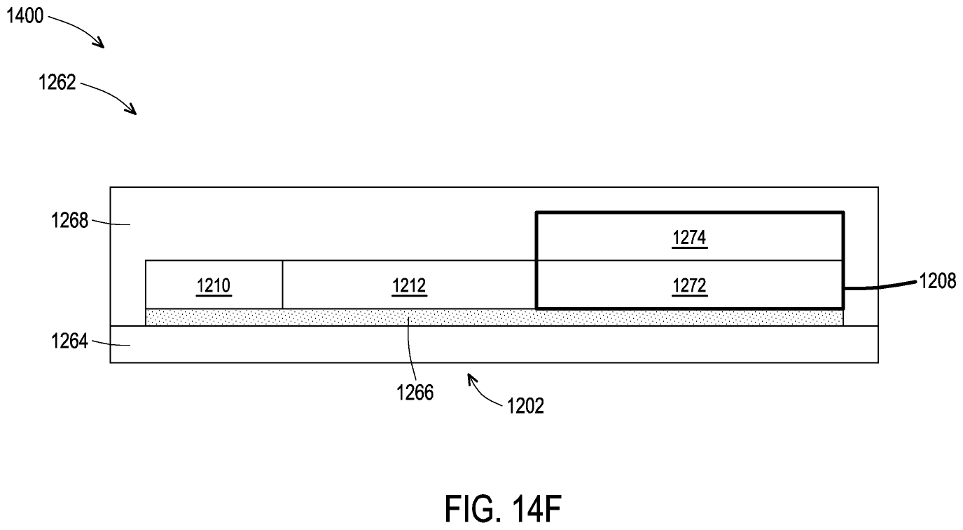

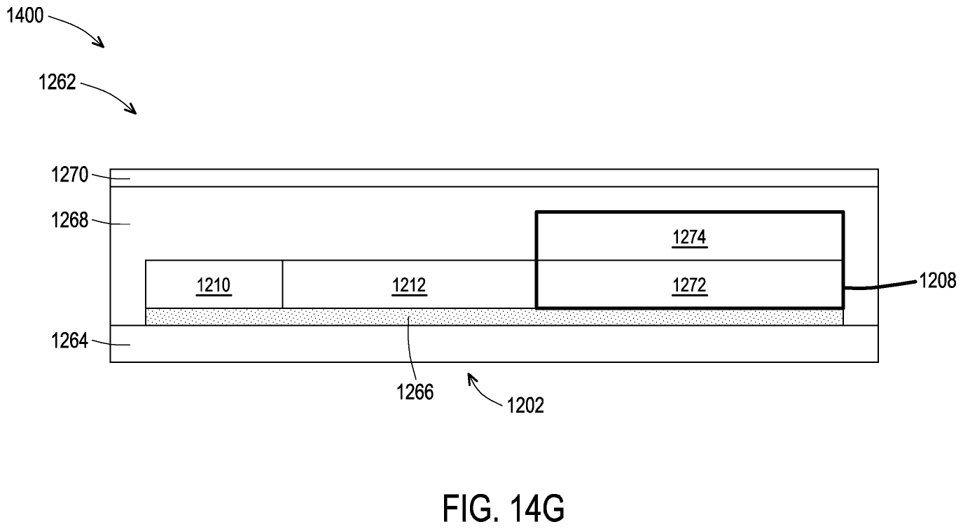

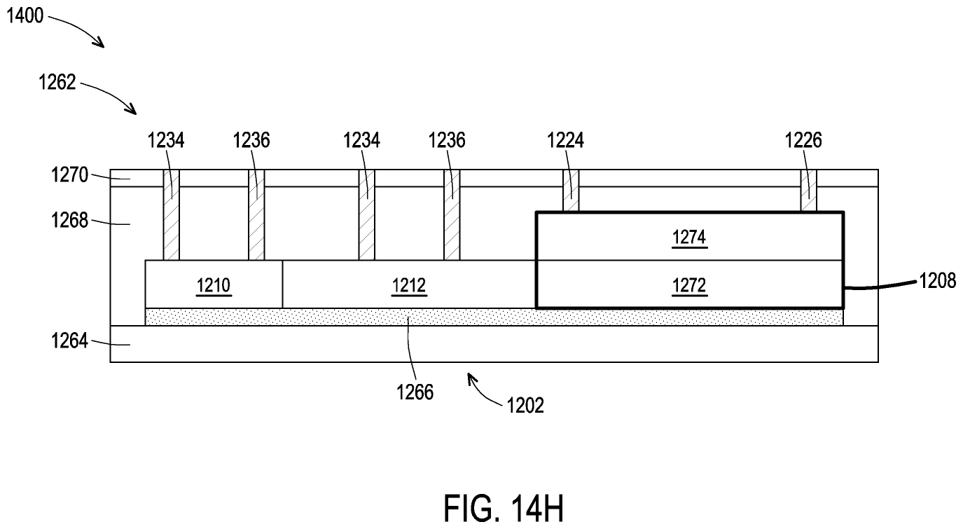

FIGS. 14A-14H are diagrams of an example 1400 of forming a resistive sensor structure 1202 described herein. In some implementations, one or more of the semiconductor processing techniques and/or operations described in connection with FIGS. 14A-14H may be used and/or performed to form one or more of the other resistive sensor structures described herein. In some implementations, one or more of the semiconductor processing operations described in connection with FIGS. 14A-14H are performed using one or more of the semiconductor processing tools 102-112 and/or the wafer/die transport tool 114. In some implementations, one or more of the semiconductor processing operations described in connection with FIGS. 14A-14H are performed using another semiconductor processing tool.

As shown in FIG. 14A, the dielectric layer 1266 may be formed above the substrate 1264. A deposition tool 102 may be used to deposit the dielectric layer 1266 using a PVD technique, an ALD technique, a CVD technique, an oxidation technique, another type of deposition technique described in connection with FIG. 1, and/or another suitable deposition technique. The dielectric layer 1266 may be deposited in one or more deposition operations. In some implementations, a planarization tool 110 may be used to planarize the dielectric layer 1266 after the dielectric layer 1266 is deposited. In some implementations, a thickness of the dielectric layer 1266 is included in a range of approximately 100 angstroms to approximately 300 angstroms. However, other values for the range are within the scope of the present disclosure.

As shown in FIG. 14B, a TCR-reducing layer 1402 is formed on the dielectric layer 1266. A deposition tool 102 may be used to deposit the TCR-reducing layer 1402 using a PVD technique, an ALD technique, a CVD technique, an oxidation technique, another type of deposition technique described in connection with FIG. 1, and/or another suitable deposition technique. The TCR-reducing layer 1402 may be deposited in one or more deposition operations. In some implementations, a planarization tool 110 may be used to planarize the TCR-reducing layer 1402 after the TCR-reducing layer 1402 is deposited. In some implementations, a thickness of the TCR-reducing layer 1402 is included in a range of approximately 400 angstroms to approximately 600 angstroms. However, other values for the range are within the scope of the present disclosure.

As shown in FIG. 14C, the TCR-reducing layer 1402 is etched to remove a portion of the TCR-reducing layer 1402. In some implementations, a pattern in a photoresist layer is used to etch the TCR-reducing layer 1402. In these implementations, a deposition tool 102 may be used to form the photoresist layer on the TCR-reducing layer 1402. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the TCR-reducing layer 1402 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the TCR-reducing layer 1402 based on a pattern.

As shown in FIG. 14D, a TCR-increasing layer 1404 is formed on the dielectric layer 1266 and on the TCR-reducing layer 1402. A deposition tool 102 may be used to deposit the TCR-increasing layer 1404 using a PVD technique, an ALD technique, a CVD technique, an oxidation technique, another type of deposition technique described in connection with FIG. 1, and/or another suitable deposition technique. The TCR-increasing layer 1404 may be deposited in one or more deposition operations. In some implementations, a planarization tool 110 may be used to planarize the TCR-increasing layer 1404 after the TCR-increasing layer 1404 is deposited. In some implementations, a thickness of the TCR-increasing layer 1404 is included in a range of approximately 1000 angstroms to approximately 1200 angstroms. However, other values for the range are within the scope of the present disclosure.

As shown in FIG. 14E, the TCR-increasing layer 1404 is etched to remove a portion of the TCR-increasing layer 1404 on the TCR-reducing layer 1402. In some implementations, a pattern in a photoresist layer is used to etch the TCR-increasing layer 1404. In these implementations, a deposition tool 102 may be used to form the photoresist layer on the TCR-increasing layer 1404. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the TCR-increasing layer 1404 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the TCR-increasing layer 1404 based on a pattern.

As shown in FIG. 14E, a portion of the TCR-increasing layer 1404 may be removed to define the sections 1272 and 1274 (e.g., respectively from the TCR-reducing layer 1402 and the TCR-increasing layer 1404) of the main thin-film resistor 1208 of the resistive sensor structure 1202, to define one or more selectable thin-film resistors 1210 (e.g., from the TCR-increasing layer 1404) of the resistive sensor structure 1202, and/or to define one or more selectable thin-film resistors 1212 (e.g., from the TCR-reducing layer 1402) of the resistive sensor structure 1202.

As shown in FIG. 14F, the dielectric layer 1268 may be formed over the resistive sensor structure 1202. A deposition tool 102 may be used to deposit the dielectric layer 1268 using a PVD technique, an ALD technique, a CVD technique, an oxidation technique, another type of deposition technique described in connection with FIG. 1, and/or another suitable deposition technique. The dielectric layer 1268 may be deposited in one or more deposition operations. In some implementations, a planarization tool 110 may be used to planarize the dielectric layer 1268 after the dielectric layer 1268 is deposited.

As shown in FIG. 14G, the dielectric layer 1270 may be formed on the dielectric layer 1268. A deposition tool 102 may be used to deposit the dielectric layer 1270 using a PVD technique, an ALD technique, a CVD technique, an oxidation technique, another type of deposition technique described in connection with FIG. 1, and/or another suitable deposition technique. The dielectric layer 1270 may be deposited in one or more deposition operations. In some implementations, a planarization tool 110 may be used to planarize the dielectric layer 1270 after the dielectric layer 1270 is deposited.

As shown in FIG. 14H, the contacts 1224, 1226, 1234, and/or 1236 may be formed. A deposition tool 102 and/or a plating tool 112 may be used to deposit the contacts 1224, 1226, 1234, and/or 1236 using a CVD technique, a PVD technique, an ALD technique, an electroplating technique, another deposition technique described above in connection with FIG. 1, and/or another suitable deposition technique.

As indicated above, FIGS. 14A-14H are provided as examples. Other examples may differ from what is described with regard to FIGS. 14A-14H.

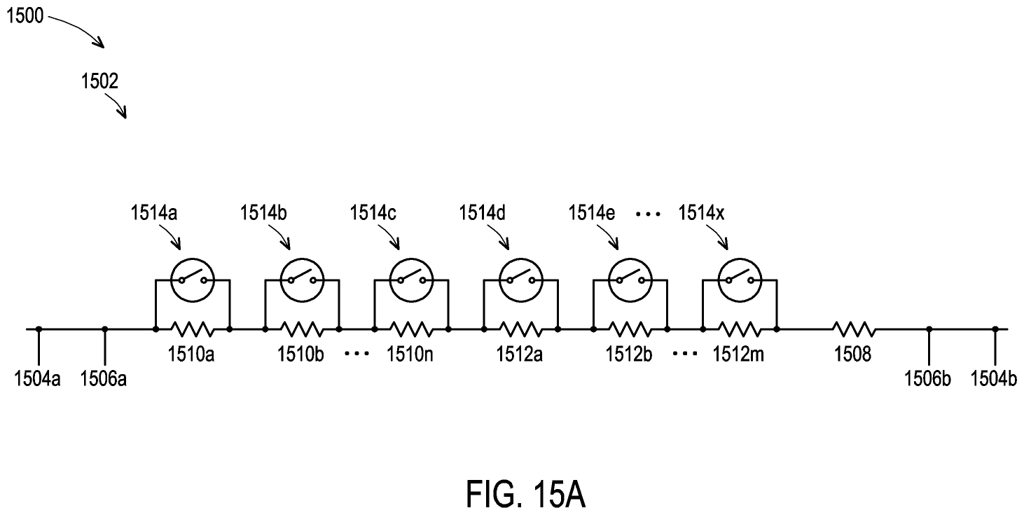

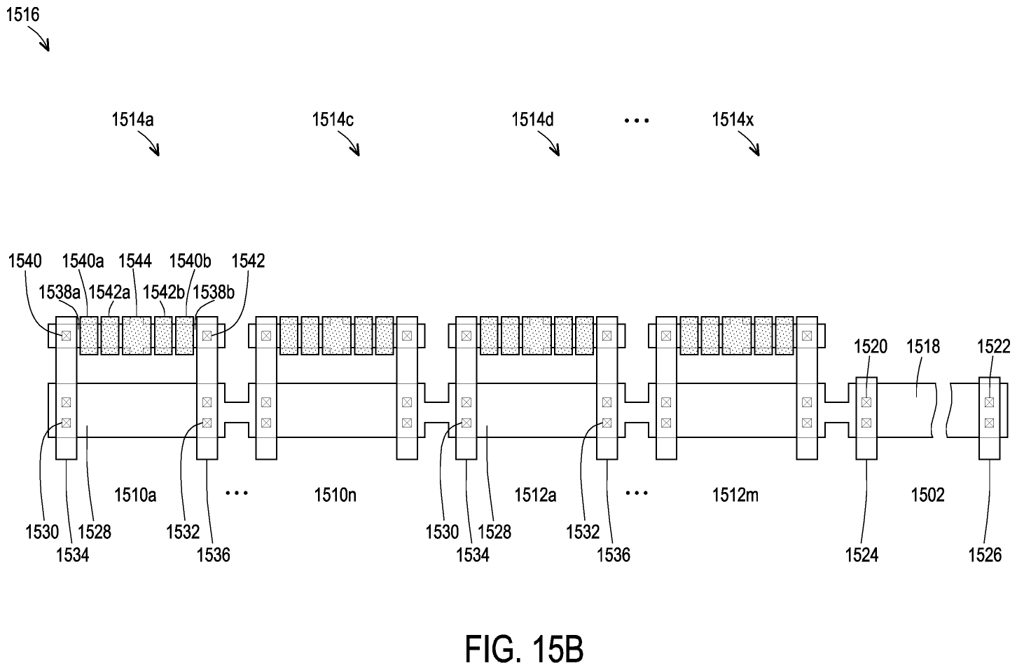

FIGS. 15A and 15B are diagrams of example implementations of a tunable resistive sensor structure described herein. FIG. 15A illustrates an example 1500 of an implementation for a resistive sensor structure 1502. The resistive sensor structure 1502 is similar to the resistive sensor structure 1202, and includes one or more inputs 1504a, 1504b, one or more sensing terminals 1506a, 1506b, a main thin-film resistor 1508, a plurality of selectable thin-film resistors 1510a-1510n (e.g., TCR-increasing resistors), a plurality of selectable thin-film resistors 1512a-1512m (e.g., TCR-reducing resistors), and a plurality of control gates 1514a-1514x. However, the control gates 1514a-1514x of the resistive sensor structure 1502 are different from the control gates 1214a-1214x of the resistive sensor structure 1202 in that the control gates 1514a-1514x include programmable gate structures similar to the control gates 512a-512n of the resistive sensor structure 502. The control gates 1514a-1514x may be implemented by one or more examples of programmable control gates illustrated and described in connection with FIGS. 5A-5I.

FIG. 15B illustrates an example 1516 of a structural implementation of the control gates 1514a-1514x of the resistive sensor structure 1502. As shown in FIG. 15B, each of the control gates 1514a-1514x may include a floating gate transistor structure that includes active regions 1538a and 1538b, word line structures 1540a and 1540b, control gate structures 1542a and 1542b, and an erase gate structure 1544. The active regions 1528 of the selectable thin-film resistors 1510a-1510n are electrically connected in series. The active regions 1528 of the selectable thin-film resistors 1512a-1512m are electrically connected in series. The active regions 1518 of the main thin-film resistor 1508 are electrically coupled in series with the active regions 1528 of the selectable thin-film resistors 1510a-1510n and of the selectable thin-film resistors 1512a-1512m. Each of a first subset of the control gates 1514a-1514x is electrically coupled in parallel with a corresponding one of the selectable thin-film resistors 1510a-1510n. Each of a second subset of the control gates 1514a-1514x is electrically coupled in parallel with a corresponding one of the selectable thin-film resistors 1512a-1512m. The control gates 1514a-1514x are also electrically coupled in series with the main thin-film resistor 1508.

As indicated above, FIGS. 15A and 15B are provided as examples. Other examples may differ from what is described with regard to FIGS. 15A and 15B.

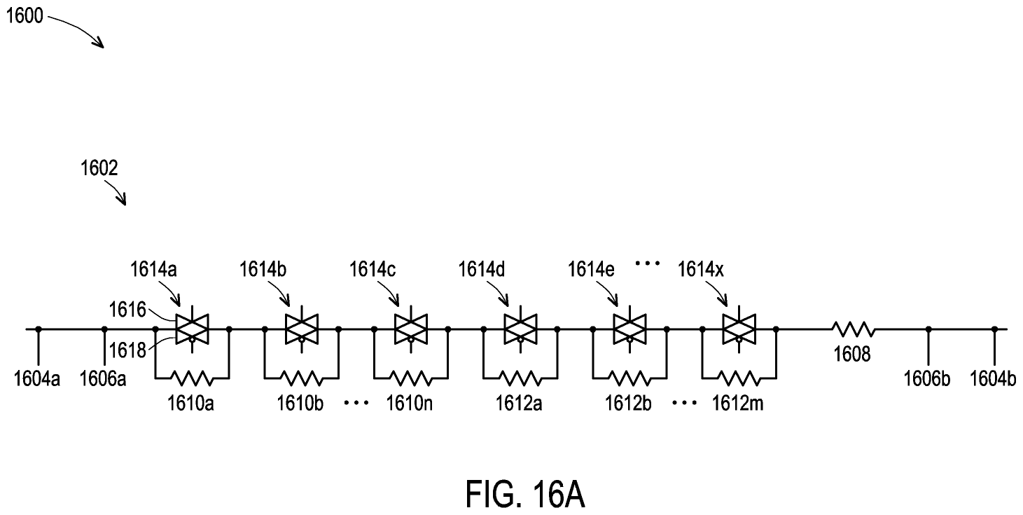

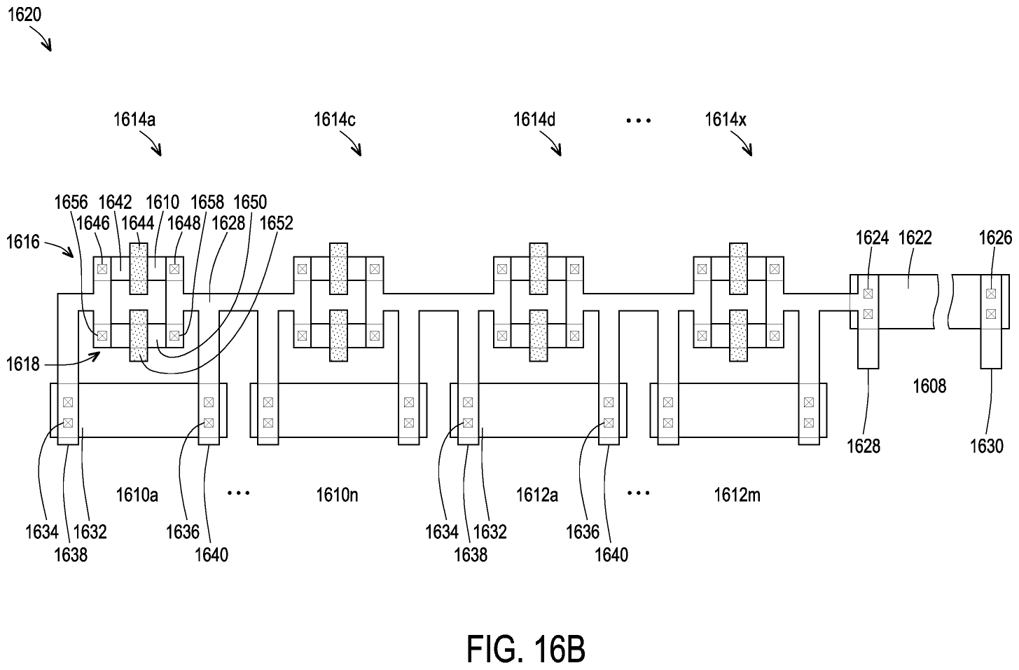

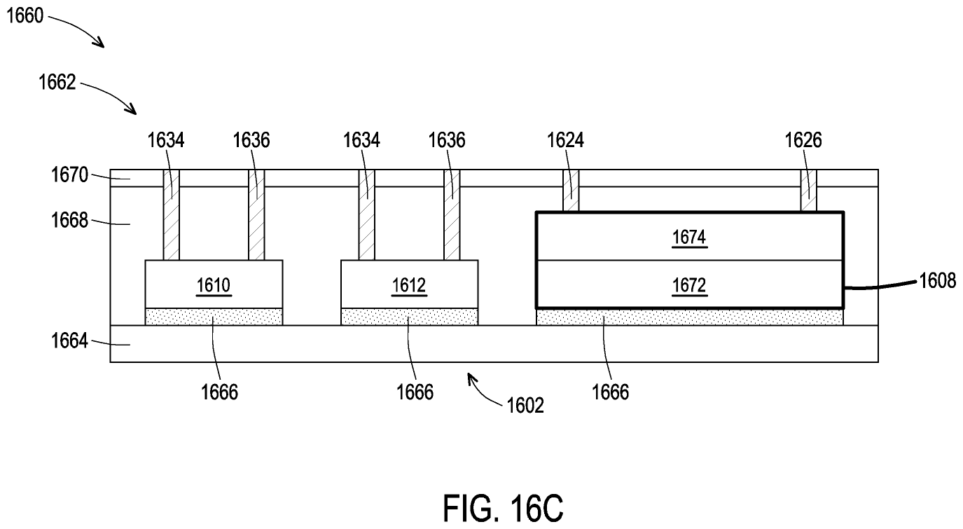

FIGS. 16A-16C are diagrams of example implementations of a tunable resistive sensor structure described herein. FIG. 16A illustrates an example 1600 of an implementation for a resistive sensor structure 1602. The resistive sensor structure 1602 is similar to the resistive sensor structure 1202, and includes one or more inputs 1604a, 1604b, one or more sensing terminals 1606a, 1606b, a main thin-film resistor 1608, a plurality of selectable thin-film resistors 1610a-1610n (e.g., TCR-increasing resistors), a plurality of selectable thin-film resistors 1612a-1612m (e.g., TCR-reducing resistors), and a plurality of control gates 1614a-1614x implemented as transmission gates that each include an NMOS transistor 1616 electrically coupled in parallel with a PMOS transistor 1618.

FIG. 16B illustrates an example 1620 of a structural implementation of the resistive sensor structure 1602. As shown in FIG. 16B, the structure implementation of the resistive sensor structure 1602 is similar to the structural implementation of the resistive sensor structure 1202. For example, the main thin-film resistor 1608 includes an active region 1622, contacts 1624 and 1626, and metallization layers 1628 and 1630; the selectable thin-film resistors 1610a-1610n and 1612a-1612m each include an active region 1632, contacts 1634 and 1636, and metallization layers 1638 and 1640; and the control gates 1614a-1614x each include an NMOS transistor 1616 (e.g., that includes an active region 1642, a gate structure 1644, contacts 1646 and 1648) and a PMOS transistor 1618 (e.g., that includes an active region 1650, a gate structure 1652, and contacts 1656 and 1658).

However, unlike the resistive sensor structure 1202, the active region 1622 of the main thin-film resistor 1608, the active regions 1632 of the selectable thin-film resistors 1610a-1610n, and the active regions 1632 of the selectable thin-film resistors 1612a-1612m are not directly connected and are instead physically isolated. Instead, the main thin-film resistor 1608 is electrically coupled in series with the selectable thin-film resistors 1610a-1610n and the selectable thin-film resistors 1612a-1612m through the metallization layers 1628, 1630, 1638, and/or 1640. The main thin-film resistor 1608 is also electrically coupled in series with the control gates 1614a-1614x through the metallization layers 1628, 1630, 1638, and/or 1640. Each of a first subset of the control gates 1614a-1614x is electrically coupled in parallel with a corresponding one of the selectable thin-film resistors 1610a-1610n. Each of a second subset of the control gates 1612a-1614x is electrically coupled in parallel with a corresponding one of the selectable thin-film resistors 1612a-1612m.

FIG. 16C illustrates an example 1660 of a structural implementation of a semiconductor device 1662 in which a resistive sensor structure 1602 may be included. The semiconductor device 1662 may include a substrate 1664 and a plurality of dielectric layers 1666, 1668, and 1670. The resistive sensor structure 1602 may include the main thin-film resistor 1608, which may include one or more resistive sections 1672 and 1674 that are vertically arranged in the semiconductor device 1662. In some implementations, the section 1672 is a TCR-reducing section and the section 1674 is a TCR-increasing section. The main thin-film resistor 1608 is electrically coupled with contacts 1624 and 1626.

A selectable thin-film resistor 1610 includes a TCR-increasing material, and is electrically coupled with a set of contacts 1634 and 1636. A selectable thin-film resistor 1612 may be located between the selectable thin-film resistor 1610 and the main thin-film resistor 1608, and may include a TCR-reducing material. The selectable thin-film resistor 1612 may be electrically coupled with another set of contacts 1634 and 1636. The main thin-film resistor 1608, the selectable thin-film resistor(s) 1610, and the selectable thin-film resistors(s) 1612 are physically isolated from each other in the semiconductor device 1662, as shown in the example 1660 in FIG. 16C.

As indicated above, FIGS. 16A-16C are provided as examples. Other examples may differ from what is described with regard to FIGS. 16A-16C.

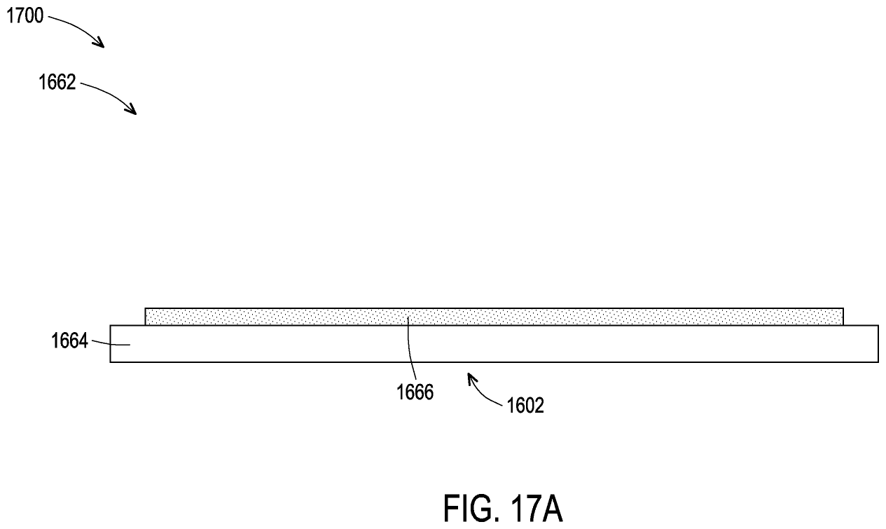

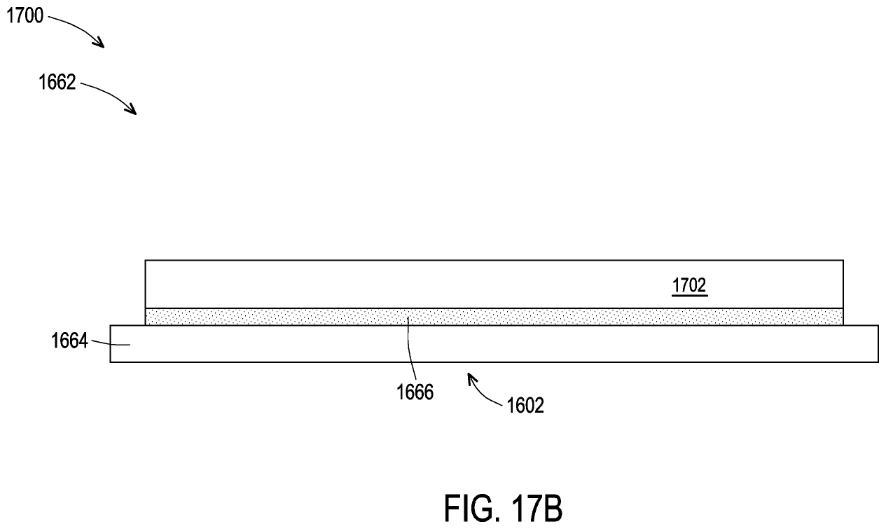

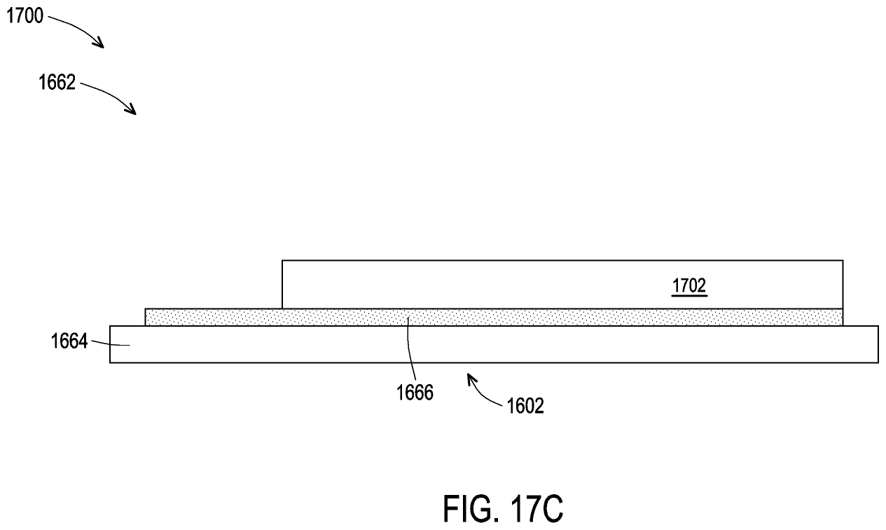

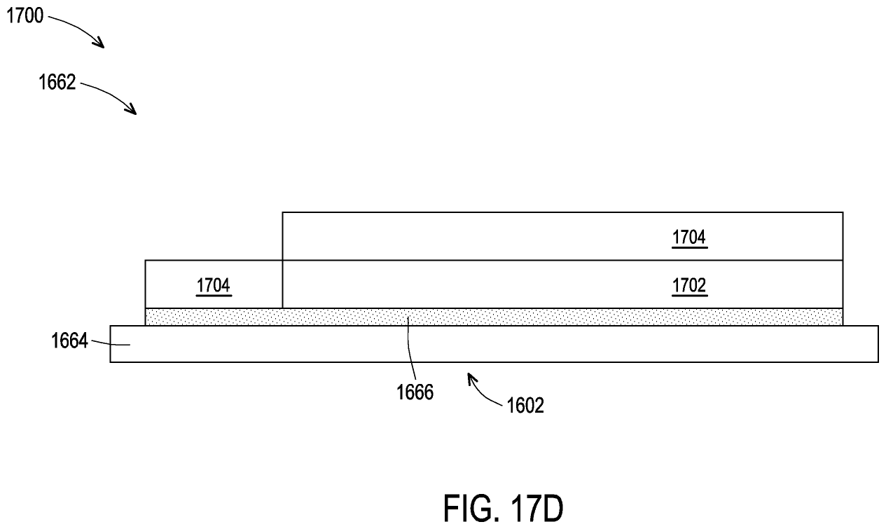

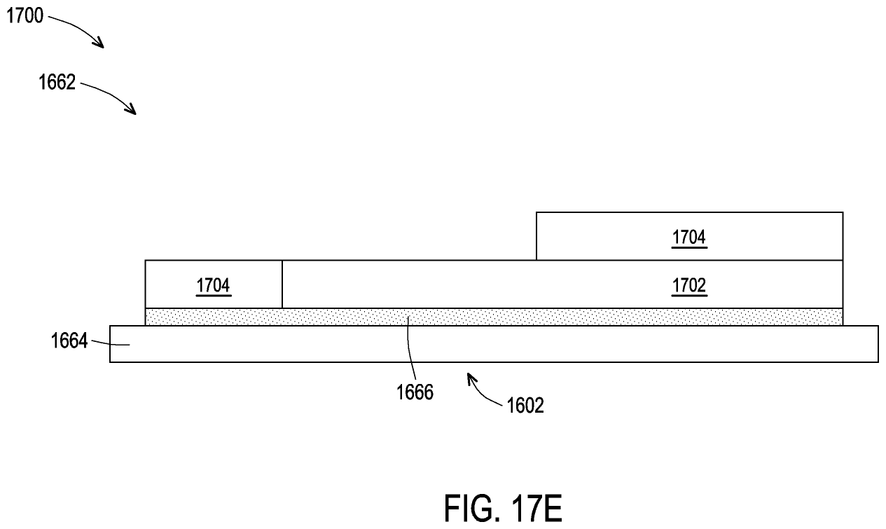

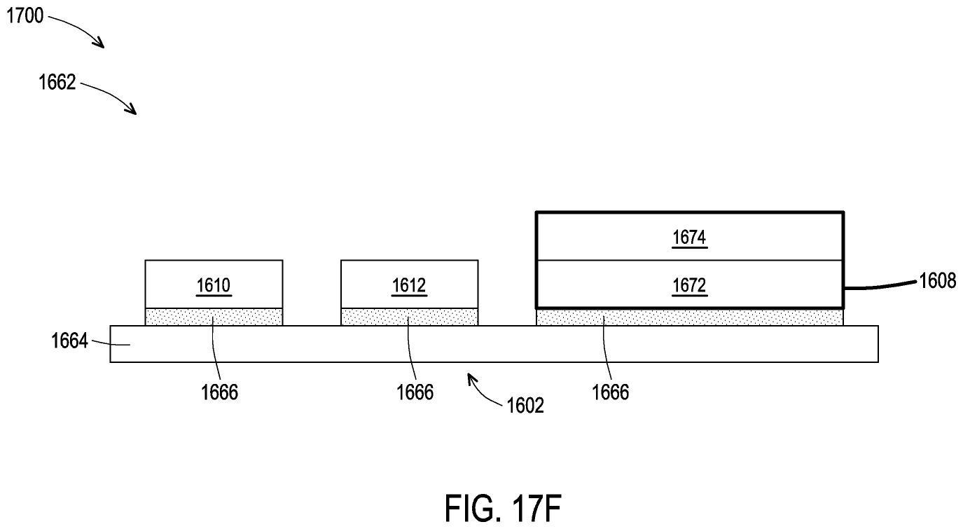

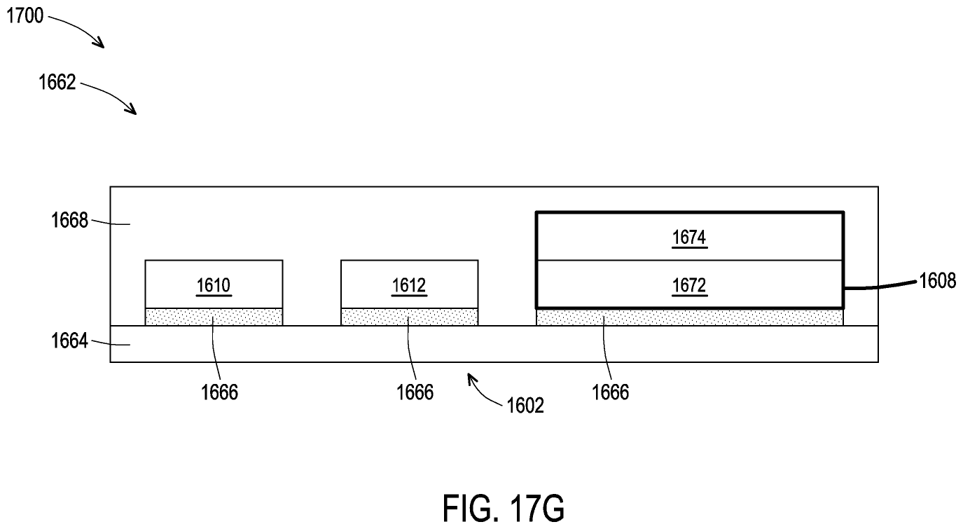

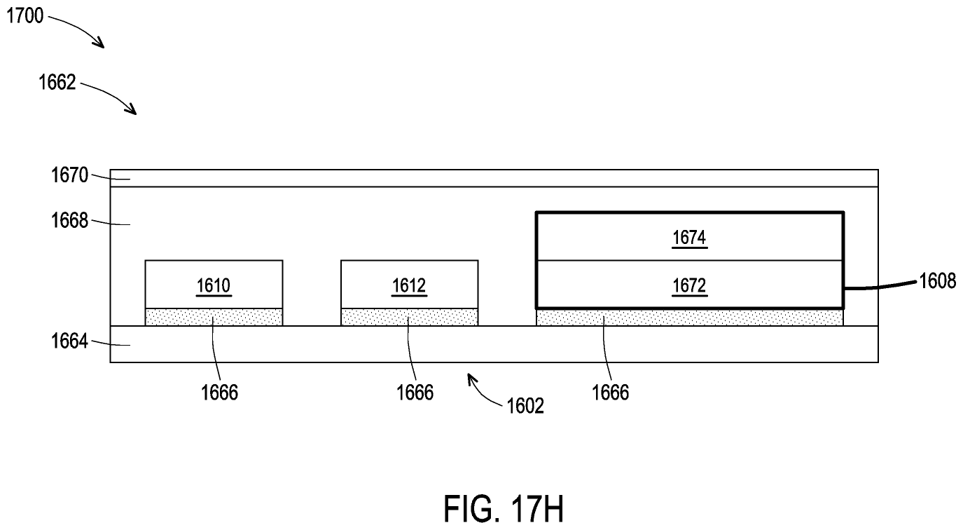

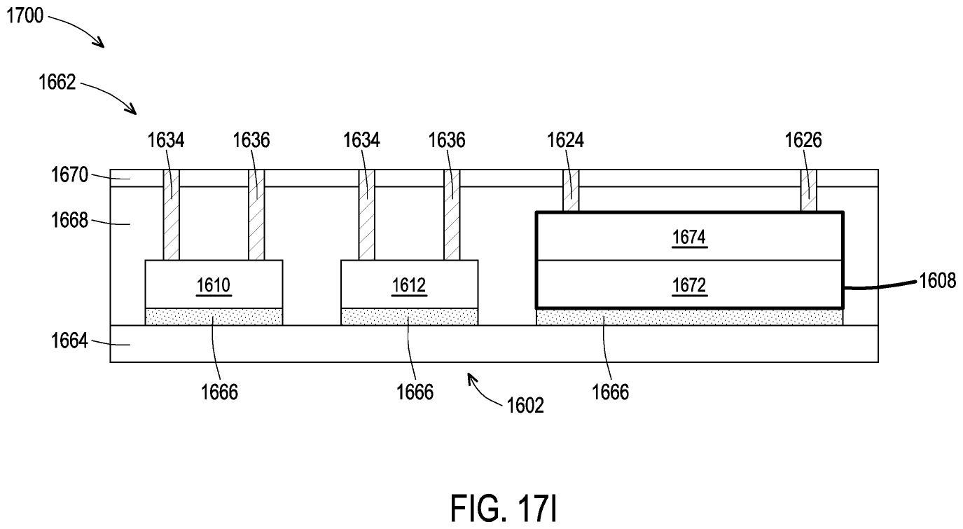

FIGS. 17A-17I are diagrams of an example 1700 of forming a resistive sensor structure 1602 described herein. In some implementations, one or more of the semiconductor processing techniques and/or operations described in connection with FIGS. 17A-17I may be used and/or performed to form one or more of the other resistive sensor structures described herein. In some implementations, one or more of the semiconductor processing operations described in connection with FIGS. 17A-17I are performed using one or more of the semiconductor processing tools 102-112 and/or the wafer/die transport tool 114. In some implementations, one or more of the semiconductor processing operations described in connection with FIGS. 17A-17I are performed using another semiconductor processing tool.

As shown in FIG. 17A, the dielectric layer 1666 may be formed above the substrate 1264. A deposition tool 102 may be used to deposit the dielectric layer 1666 using a PVD technique, an ALD technique, a CVD technique, an oxidation technique, another type of deposition technique described in connection with FIG. 1, and/or another suitable deposition technique. The dielectric layer 1666 may be deposited in one or more deposition operations. In some implementations, a planarization tool 110 may be used to planarize the dielectric layer 1666 after the dielectric layer 1666 is deposited. In some implementations, a thickness of the dielectric layer 1666 is included in a range of approximately 100 angstroms to approximately 300 angstroms. However, other values for the range are within the scope of the present disclosure.

As shown in FIG. 17B, a TCR-reducing layer 1702 is formed on the dielectric layer 1666. A deposition tool 102 may be used to deposit the TCR-reducing layer 1702 using a PVD technique, an ALD technique, a CVD technique, an oxidation technique, another type of deposition technique described in connection with FIG. 1, and/or another suitable deposition technique. The TCR-reducing layer 1702 may be deposited in one or more deposition operations. In some implementations, a planarization tool 110 may be used to planarize the TCR-reducing layer 1702 after the TCR-reducing layer 1702 is deposited. In some implementations, a thickness of the TCR-reducing layer 1702 is included in a range of approximately 400 angstroms to approximately 600 angstroms. However, other values for the range are within the scope of the present disclosure.

As shown in FIG. 17C, the TCR-reducing layer 1702 is etched to remove a portion of the TCR-reducing layer 1702. In some implementations, a pattern in a photoresist layer is used to etch the TCR-reducing layer 1702. In these implementations, a deposition tool 102 may be used to form the photoresist layer on the TCR-reducing layer 1702. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the TCR-reducing layer 1702 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the TCR-reducing layer 1702 based on a pattern.

As shown in FIG. 17D, a TCR-increasing layer 1704 is formed on the dielectric layer 1666 and on the TCR-reducing layer 1702. A deposition tool 102 may be used to deposit the TCR-increasing layer 1704 using a PVD technique, an ALD technique, a CVD technique, an oxidation technique, another type of deposition technique described in connection with FIG. 1, and/or another suitable deposition technique. The TCR-increasing layer 1704 may be deposited in one or more deposition operations. In some implementations, a planarization tool 110 may be used to planarize the TCR-increasing layer 1704 after the TCR-increasing layer 1704 is deposited. In some implementations, a thickness of the TCR-increasing layer 1704 is included in a range of approximately 1000 angstroms to approximately 1200 angstroms. However, other values for the range are within the scope of the present disclosure.

As shown in FIG. 17E, the TCR-increasing layer 1704 is etched to remove a portion of the TCR-increasing layer 1704 on the TCR-reducing layer 1702. In some implementations, a pattern in a photoresist layer is used to etch the TCR-increasing layer 1704. In these implementations, a deposition tool 102 may be used to form the photoresist layer on the TCR-increasing layer 1704. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the TCR-increasing layer 1704 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the TCR-increasing layer 1704 based on a pattern.

As shown in FIG. 17F, a subsequent etch is performed to remove additional portions of the TCR-reducing layer 1702 and additional portions of the TCR-increasing layer 1704. This etch may be performed to define the sections 1672 and 1674 (e.g., respectively from the TCR-reducing layer 1702 and the TCR-increasing layer 1704) of the main thin-film resistor 1608 of the resistive sensor structure 1602, to define one or more selectable thin-film resistors 1610 (e.g., from the TCR-increasing layer 1704) of the resistive sensor structure 1602, and to define one or more selectable thin-film resistors 1612 (e.g., from the TCR-reducing layer 1702) of the resistive sensor structure 1602. The main thin-film resistor 1608, the selectable thin-film resistor(s) 1610, and the selectable thin-film resistor(s) 1612 are defined such that the main thin-film resistor 1608, the selectable thin-film resistor(s) 1610, and the selectable thin-film resistor(s) 1612 are electrically isolated from one another. This enables the main thin-film resistor 1608, the selectable thin-film resistor(s) 1610, and the selectable thin-film resistor(s) 1612 to be electrically connected through metallization layers 1628, 1630, 1638, and 1640.

As shown in FIG. 17G, the dielectric layer 1668 may be formed over the resistive sensor structure 1602. A deposition tool 102 may be used to deposit the dielectric layer 1668 using a PVD technique, an ALD technique, a CVD technique, an oxidation technique, another type of deposition technique described in connection with FIG. 1, and/or another suitable deposition technique. The dielectric layer 1668 may be deposited in one or more deposition operations. In some implementations, a planarization tool 110 may be used to planarize the dielectric layer 1668 after the dielectric layer 1668 is deposited.

As shown in FIG. 17H, the dielectric layer 1670 may be formed on the dielectric layer 1668. A deposition tool 102 may be used to deposit the dielectric layer 1670 using a PVD technique, an ALD technique, a CVD technique, an oxidation technique, another type of deposition technique described in connection with FIG. 1, and/or another suitable deposition technique. The dielectric layer 1670 may be deposited in one or more deposition operations. In some implementations, a planarization tool 110 may be used to planarize the dielectric layer 1670 after the dielectric layer 1670 is deposited.

As shown in FIG. 17I, the contacts 1624, 1626, 1634, and/or 1636 may be formed. A deposition tool 102 and/or a plating tool 112 may be used to deposit the contacts 1624, 1626, 1634, and/or 1636 using a CVD technique, a PVD technique, an ALD technique, an electroplating technique, another deposition technique described above in connection with FIG. 1, and/or another suitable deposition technique.

As indicated above, FIGS. 17A-17I are provided as examples. Other examples may differ from what is described with regard to FIGS. 17A-17I.

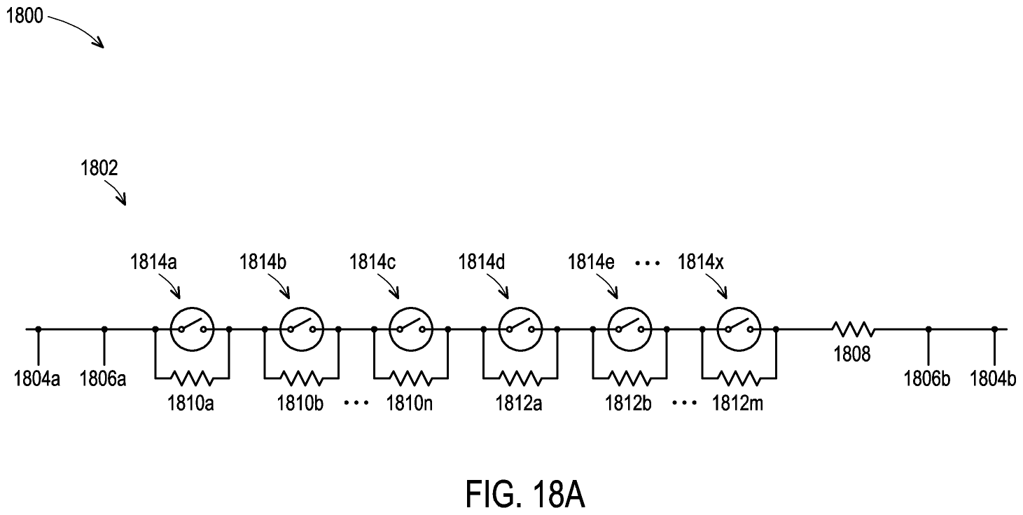

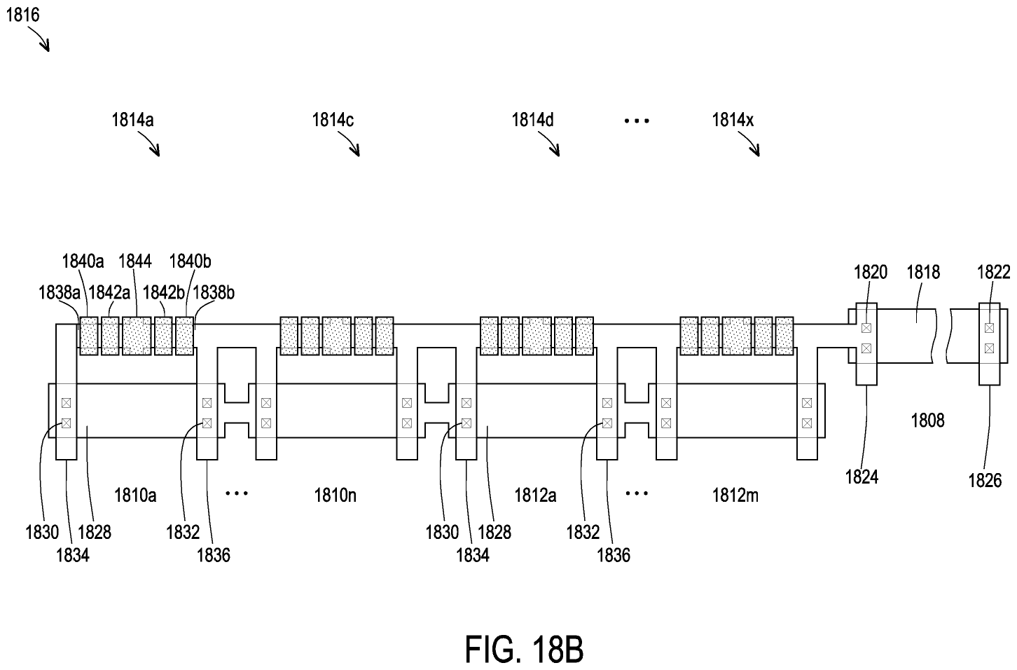

FIGS. 18A and 18B are diagrams of example implementations of a tunable resistive sensor structure described herein. FIG. 18A illustrates an example 1800 of an implementation for a resistive sensor structure 1802. The resistive sensor structure 1802 is similar to the resistive sensor structure 1602, and includes one or more inputs 1804a, 1804b, one or more sensing terminals 1806a, 1806b, a main thin-film resistor 1808, a plurality of selectable thin-film resistors 1810a-1810n (e.g., TCR-increasing resistors), a plurality of selectable thin-film resistors 1812a-1812m (e.g., TCR-reducing resistors), and a plurality of control gates 1814a-1814x. However, the control gates 1814a-1814x of the resistive sensor structure 1802 are different from the control gates 1614a-1614x of the resistive sensor structure 1602 in that the control gates 1814a-1814x include programmable gate structures similar to the control gates 512a-512n of the resistive sensor structure 502. The control gates 1814a-1814x may be implemented by one or more examples of programmable control gates illustrated and described in connection with FIGS. 5A-5I.

FIG. 18B illustrates an example 1816 of a structural implementation of the resistive sensor structure 1802. As shown in FIG. 18B, the structure implementation of the resistive sensor structure 1802 is similar to the structural implementation of the resistive sensor structure 1602. For example, the main thin-film resistor 1808 includes an active region 1818, contacts 1820 and 1822, and metallization layers 1824 and 1826; and the selectable thin-film resistors 1810a-1810n and 1812a-1812m each include an active region 1828, contacts 1830 and 1832, and metallization layers 1834 and 1836. The active region 1818 of the main thin-film resistor 1808, the active regions 1828 of the selectable thin-film resistors 1810a-1810n, and the active regions 1828 of the selectable thin-film resistors 1812a-1812m are not directly connected and are instead physically isolated. The main thin-film resistor 1808 is electrically coupled in series with the selectable thin-film resistors 1810a-1810n and the selectable thin-film resistors 1812a-1812m through the metallization layers 1824, 1826, 1834, and/or 1836. The main thin-film resistor 1808 is also electrically coupled in series with the control gates 1814a-1814x through the metallization layers 1824, 1826, 1834, and/or 1836. Each of a first subset of the control gates 1814a-1814x is electrically coupled in parallel with a corresponding one of the selectable thin-film resistors 1810a-1810n. Each of a second subset of the control gates 1814a-1814x is electrically coupled in parallel with a corresponding one of the selectable thin-film resistors 1814a-1814m.

However, each of the control gates 1814a-1814x may include a floating gate transistor structure that includes active regions 1838a and 1838b, word line structures 1840a and 1840b, control gate structures 1842a and 1842b, and an erase gate structure 1844, unlike the transmission gates of the control gates 1614a-1614x.

As indicated above, FIGS. 18A and 18B are provided as examples. Other examples may differ from what is described with regard to FIGS. 18A and 18B.

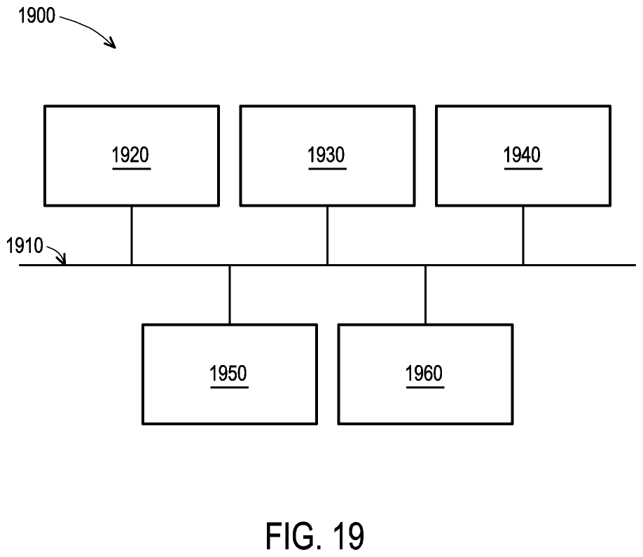

FIG. 19 is a diagram of example components of a device 1900 described herein. In some implementations, one or more of the semiconductor processing tools 102-112 and/or the wafer/die transport tool 114 may include one or more devices 1900 and/or one or more components of the device 1900. As shown in FIG. 19, the device 1900 may include a bus 1910, a processor 1920, a memory 1930, an input component 1940, an output component 1950, and/or a communication component 1960.

The bus 1910 may include one or more components that enable wired and/or wireless communication among the components of the device 1900. The bus 1910 may couple together two or more components of FIG. 19, such as via operative coupling, communicative coupling, electronic coupling, and/or electric coupling. For example, the bus 1910 may include an electrical connection (e.g., a wire, a trace, and/or a lead) and/or a wireless bus. The processor 1920 may include a central processing unit, a graphics processing unit, a microprocessor, a controller, a microcontroller, a digital signal processor, a field-programmable gate array, an application-specific integrated circuit, and/or another type of processing component. The processor 1920 may be implemented in hardware, firmware, or a combination of hardware and software. In some implementations, the processor 1920 may include one or more processors capable of being programmed to perform one or more operations or processes described elsewhere herein.

The memory 1930 may include volatile and/or nonvolatile memory. For example, the memory 1930 may include random access memory (RAM), read only memory (ROM), a hard disk drive, and/or another type of memory (e.g., a flash memory, a magnetic memory, and/or an optical memory). The memory 1930 may include internal memory (e.g., RAM, ROM, or a hard disk drive) and/or removable memory (e.g., removable via a universal serial bus connection). The memory 1930 may be a non-transitory computer-readable medium. The memory 1930 may store information, one or more instructions, and/or software (e.g., one or more software applications) related to the operation of the device 1900. In some implementations, the memory 1930 may include one or more memories that are coupled (e.g., communicatively coupled) to one or more processors (e.g., processor 1920), such as via the bus 1910. Communicative coupling between a processor 1920 and a memory 1930 may enable the processor 1920 to read and/or process information stored in the memory 1930 and/or to store information in the memory 1930.

The input component 1940 may enable the device 1900 to receive input, such as user input and/or sensed input. For example, the input component 1940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1950 may enable the device 1900 to provide output, such as via a display, a speaker, and/or a light-emitting diode. The communication component 1960 may enable the device 1900 to communicate with other devices via a wired connection and/or a wireless connection. For example, the communication component 1960 may include a receiver, a transmitter, a transceiver, a modem, a network interface card, and/or an antenna.

The device 1900 may perform one or more operations or processes described herein. For example, a non-transitory computer-readable medium (e.g., memory 1930) may store a set of instructions (e.g., one or more instructions or code) for execution by the processor 1920. The processor 1920 may execute the set of instructions to perform one or more operations or processes described herein. In some implementations, execution of the set of instructions, by one or more processors 1920, causes the one or more processors 1920 and/or the device 1900 to perform one or more operations or processes described herein. In some implementations, hardwired circuitry may be used instead of or in combination with the instructions to perform one or more operations or processes described herein. Additionally, or alternatively, the processor 1920 may be configured to perform one or more operations or processes described herein. Thus, implementations described herein are not limited to any specific combination of hardware circuitry and software.

The number and arrangement of components shown in FIG. 19 are provided as an example. The device 1900 may include additional components, fewer components, different components, or differently arranged components than those shown in FIG. 19. Additionally, or alternatively, a set of components (e.g., one or more components) of the device 1900 may perform one or more functions described as being performed by another set of components of the device 1900.

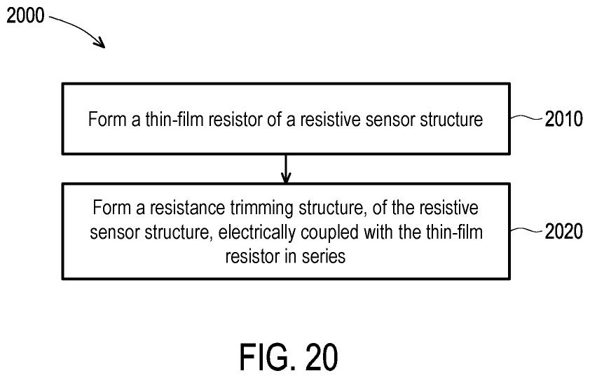

FIG. 20 is a flowchart of an example process 2000 associated with forming a resistive sensor structure described herein. In some implementations, one or more process blocks of FIG. 20 are performed using one or more semiconductor processing tools (e.g., one or more of the semiconductor processing tools 102-112). Additionally, or alternatively, one or more process blocks of FIG. 20 may be performed using one or more components of device 1900, such as processor 1920, memory 1930, input component 1940, output component 1950, and/or communication component 1960.

As shown in FIG. 20, process 2000 may include forming a thin-film resistor of a resistive sensor structure (block 2010). For example, one or more of the semiconductor processing tools 102-112 may be used to form a thin-film resistor (e.g., a thin-film resistor 208, 508, 608, 808, 908, 1108, 1208, 1508, 1608, and/or 1808) of a resistive sensor structure (e.g., a resistive sensor structure 202, 502, 602, 802, 902, 1102, 1202, 1502, 1602, and/or 1802), as described herein.

As further shown in FIG. 20, process 2000 may include forming a resistance trimming structure, of the resistive sensor structure, electrically coupled with the thin-film resistor in series (block 2020). For example, one or more of the semiconductor processing tools 102-112 may be used to form a resistance trimming structure (e.g., thin-film resistors 210a-210n, thin-film resistors 510a-510n, resistance trimming structure 610, resistance trimming structure 810, resistance trimming structure 910, resistance trimming structure 1110, thin-film resistors 1210a-1210n, thin-film resistors 1212a-1212m, thin-film resistors 1510a-1510n, thin-film resistors 1512a-1512m, thin-film resistors 1610a-1610n, thin-film resistors 1612a-1612m, thin-film resistors 1810a-1810n, thin-film resistors 1812a-1812m), of the resistive sensor structure, electrically coupled with the thin-film resistor in series, as described herein.

Process 2000 may include additional implementations, such as any single implementation or any combination of implementations described below and/or in connection with one or more other processes described elsewhere herein.

In a first implementation, the thin-film resistor is a first thin-film resistor of the resistive sensor structure, and the resistance trimming structure comprises a plurality of second thin-film resistors (e.g., thin-film resistors 210a-210n, thin-film resistors 510a-510n, thin-film resistors 1210a-1210n, thin-film resistors 1212a-1212m, thin-film resistors 1510a-1510n, thin-film resistors 1512a-1512m, thin-film resistors 1610a-1610n, thin-film resistors 1612a-1612m, thin-film resistors 1810a-1810n, thin-film resistors 1812a-1812m) electrically coupled with the first thin-film resistor in series, and a plurality of control gates (e.g., control gates 212a-212n, control gates 512a-512n, control gates 1214a-1214x, control gates 1514a-1514x, control gates 1614a-1614x, control gates 1814a-1814x) electrically coupled with the first thin-film resistor in series.

In a second implementation, alone or in combination with the first implementation, the plurality of second thin-film resistors are electrically coupled in series, and the plurality of control gates are electrically coupled in series.

In a third implementation, alone or in combination with one or more of the first and second implementations, respective ones of the plurality of control gates are electrically coupled with respective ones of the plurality of second thin-film resistors in parallel.

In a fourth implementation, alone or in combination with one or more of the first through third implementations, the resistance trimming structure comprises a plurality of electrically conductive sensing lines (e.g., sensing lines 614, sensing lines 814, sensing lines 914, sensing lines 1114) electrically coupled with the thin-film resistor, a plurality of resistance trimming pads (e.g., resistance trimming pads 612, resistance trimming pads 812, resistance trimming pads 912, resistance trimming pads 1112) electrically coupled with the plurality of conductive sensing lines, and a plurality of control gates (e.g., control gates 620, control gates 818, control gates 918, control gates 1116) electrically coupled with the plurality of resistance trimming pads.

In a fifth implementation, alone or in combination with one or more of the first through fourth implementations, respective ones of the resistance trimming pads are electrically coupled with respective ones of the plurality of control gates and respective ones of the electrically conductive sensing lines.

In a sixth implementation, alone or in combination with one or more of the first through fifth implementations, the plurality of resistance trimming pads are electrically coupled in series.

Although FIG. 20 shows example blocks of process 2000, in some implementations, process 2000 includes additional blocks, fewer blocks, different blocks, or differently arranged blocks than those depicted in FIG. 20. Additionally, or alternatively, two or more of the blocks of process 2000 may be performed in parallel.

In this way, some resistive sensor structures described herein include a main thin-film resistor segment and one or more selectable thin-film resistor segments that are connected in series (e.g., together and with the main thin-film resistor). The selectable thin-film resistor segment(s) of a resistive sensor structure described herein are capable of being selectively activated and/or deactivated based on the desired resistance and/or TCR for the resistive sensor structure. Various structural implementations of control gates that may be used to selectively activate and/or deactivate one or more of the selectable thin-film resistors are disclosed herein.

As described in greater detail above, some implementations described herein provide a method. The method includes forming a thin-film resistor of a resistive sensor structure. The method includes forming a resistance trimming structure, of the resistive sensor structure, electrically coupled with the thin-film resistor in series.

As described in greater detail above, some implementations described herein provide a resistive sensor structure. The resistive sensor structure includes a first thin-film resistor. The resistive sensor structure includes a plurality of second thin-film resistors electrically coupled with the first thin-film resistor in series, where the plurality of second thin-film resistors are electrically coupled in series. The resistive sensor structure includes a plurality of control gates electrically coupled with the first thin-film resistor in series, where the plurality of control gates are electrically coupled in series, and where respective ones of the plurality of control gates are electrically coupled with respective ones of the plurality of second thin-film resistors in parallel.

As described in greater detail above, some implementations described herein provide a resistive sensor structure. The resistive sensor structure includes a thin-film resistor. The resistive sensor structure includes a resistance trimming structure electrically coupled with the thin-film resistor by a plurality of electrically conductive sensing lines. The resistive sensor structure includes a plurality of control gates electrically coupled with the resistance trimming structure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a thin-film resistor of a resistive sensor structure; and
forming a resistance trimming structure, of the resistive sensor structure, electrically coupled with the thin-film resistor in series.

2. The method of claim 1, wherein the thin-film resistor is a first thin-film resistor of the resistive sensor structure; and
wherein the resistance trimming structure comprises:
a plurality of second thin-film resistors electrically coupled with the first thin-film resistor in series; and
a plurality of control gates electrically coupled with the first thin-film resistor in series.

3. The method of claim 2, wherein the plurality of second thin-film resistors are electrically coupled in series; and
wherein the plurality of control gates are electrically coupled in series.

4. The method of claim 2, wherein respective ones of the plurality of control gates are electrically coupled with respective ones of the plurality of second thin-film resistors in parallel.

5. The method of claim 1, wherein the resistance trimming structure comprises:
a plurality of electrically conductive sensing lines electrically coupled with the thin-film resistor;
a plurality of resistance trimming pads electrically coupled with the plurality of conductive sensing lines; and
a plurality of control gates electrically coupled with the plurality of resistance trimming pads.

6. The method of claim 1, wherein the resistance trimming structure comprises a plurality of resistance trimming pads; and
wherein respective ones of the resistance trimming pads are electrically coupled with respective ones of the plurality of control gates and respective ones of the electrically conductive sensing lines.

7. The method of claim 6, wherein the plurality of resistance trimming pads are electrically coupled with the thin film resistor in parallel.

8. A resistive sensor structure, comprising:
a first thin-film resistor;
a plurality of second thin-film resistors electrically coupled with the first thin-film resistor in series,
wherein the plurality of second thin-film resistors are electrically coupled in series; and
a plurality of control gates electrically coupled with the first thin-film resistor in series,
wherein the plurality of control gates are electrically coupled in series, and
wherein respective ones of the plurality of control gates are electrically coupled with respective ones of the plurality of second thin-film resistors in parallel.

9. The resistive sensor structure of claim 8, wherein the plurality of control gates comprise a plurality of transmission gates; and
wherein each of the plurality of transmission gates comprises:
a p-type metal oxide semiconductor (PMOS) transistor; and
an n-type metal oxide semiconductor (NMOS) transistor electrically coupled with the PMOS transistor in parallel.

10. The resistive sensor structure of claim 8, wherein the plurality of control gates comprise a plurality of electrically programmable control gates.

11. The resistive sensor structure of claim 10, wherein the plurality of electrically programmable control gates comprise at least one of:
a plurality of p-type metal oxide semiconductor (PMOS) transistors,
a plurality of n-type metal oxide semiconductor (NMOS) transistors,
a plurality of negative-positive-negative bipolar junction transistors (NPN BJTs),
a plurality of positive-negative-positive bipolar junction transistors (PNP BJTs),
a plurality of floating gate transistors, or
a plurality of resistive random access memory (RRAM) structures.

12. The resistive sensor structure of claim 8, wherein the first thin-film resistor is electrically coupled in series with the plurality of second thin-film resistors through a first active region of the first thin-film resistor and through a plurality of second active regions of the plurality of second thin-film resistors; and
wherein the second thin-film resistors are electrically coupled in series through the plurality of second active regions of the plurality of second thin-film resistors.

13. The resistive sensor structure of claim 8, wherein the first thin-film resistor is electrically coupled in series with the plurality of second thin-film resistors through a plurality of metallization layers; and
wherein the second thin-film resistors are electrically coupled in series through the plurality of metallization layers.

14. The resistive sensor structure of claim 8, wherein the plurality of second thin-film resistors comprise:
one or more thermal coefficient of resistance increasing (TCR-increasing) thin-film resistors; and
one or more thermal coefficient of resistance reducing (TCR-reducing) thin-film resistors.

15. A resistive sensor structure, comprising:
a thin-film resistor;
a resistance trimming structure electrically coupled with the thin-film resistor by a plurality of electrically conductive sensing lines; and
a plurality of control gates electrically coupled with the resistance trimming structure.

16. The resistive sensor structure of claim 15, wherein the resistance trimming structure comprises a plurality of resistance trimming pads that are electrically coupled in series; and
wherein respective ones of the resistance trimming pads are electrically coupled with respective ones of the plurality of control gates and respective ones of the electrically conductive sensing lines.

17. The resistive sensor structure of claim 16, wherein each of the plurality of resistance trimming pads comprises a burn-out region.

18. The resistive sensor structure of claim 16, wherein the plurality of control gates comprise a plurality of transmission gates.

19. The resistive sensor structure of claim 16, wherein the plurality of control gates comprise a plurality of programmable control gates.

20. The resistive sensor structure of claim 15, wherein the resistance trimming structure comprises a plurality of resistance trimming pads; and
wherein respective ones of the resistance trimming pads are electrically coupled with respective ones of the plurality of control gates and respective ones of the electrically conductive sensing lines.
